(19) United States
(12) Patent Application Publication
(10) Pub. No.: US 2025/0293118 A1
(43) Pub. Date: Sep. 18, 2025

(54) COOLER, SEMICONDUCTOR DEVICE, AND VEHICLE

(71) Applicant: FUJI ELECTRIC CO., LTD., Kawasaki-shi (JP)

(72) Inventor: Yoshihiro TATEISHI, Kawasaki-shi (JP)

(73) Assignee: FUJI ELECTRIC CO., LTD., Kawasaki-shi (JP)

(21) Appl. No.: 19/224,114

(22) Filed: May 30, 2025

Related U.S. Application Data
(63) Continuation of application No. PCT/JP2024/017198, filed on May 9, 2024.

(30) Foreign Application Priority Data
Jun. 20, 2023 (JP) 2023-100938

(51) Int. Cl. H01L 23/46; H01L 23/00; H01L 23/433; H01L 25/065; H10D 80/30

(52) U.S. Cl. CPC H01L 23/46; H01L 23/433; H01L 25/0655; H10D 80/30; H01L 24/32; H01L 24/40; H01L 24/48; H01L 24/73; H01L 2224/32227; H01L 2224/32238; H01L 2224/40229; H01L 2224/48227; H01L 2224/73221; H01L 2224/73263; H01L 2224/73265; H01L 2924/13055

(57) ABSTRACT

A cooler includes a top plate having a heat dissipation surface, a bottom plate, a plurality of fins each connected to the heat dissipation surface, a peripheral wall surrounding the fins between the top plate and the bottom plate, and a refrigerant inlet and outlet provided at respective two ends of the peripheral wall in a first direction. Each fin has an inclined portion extending in an extending direction with first and second ends, and is inclined such that the second end is displaced toward the inlet relative to the first end in a first side view and toward one of opposite sides of the peripheral wall in a second direction perpendicular to the first direction relative to the first end in a second side view. The first and second side views are side views of the cooler viewed from the second direction and the first direction, respectively.

### CROSS REFERENCE TO RELATED APPLICATIONS

This is a continuation application of International Application PCT/JP2024/017198 filed on May 9, 2024 which claims priority from a Japanese Patent Application No. 2023-100938 filed on Jun. 20, 2023, the contents of which are incorporated herein by reference.

### TECHNICAL FIELD

The present invention relates to a cooler, a semiconductor device, and a vehicle.

### BACKGROUND ART

A semiconductor device used in an electric power convertor such as an inverter includes a cooler that circulates refrigerant for dissipating heat generated from a semiconductor element. This type of cooler is provided with a plurality of fins in a flow path for circulating refrigerant (e.g., Patent literature 1 to Patent Literature 5).

### CITATION LIST

### Patent Literature

Patent Literature 1: JP 3469475 B2
Patent Literature 2: JP 2018-207017 A
Patent Literature 3: JP 5901343 B2
Patent Literature 4: JP 6138197 B2
Patent Literature 5: JP 3236137 B2

### SUMMARY OF INVENTION

### Technical Problem

It is desirable for the above-described semiconductor device to improve the cooling performance of the cooler.

The present invention has been made in view of such a point, and an object of the present invention is to improve the cooling performance of a cooler applied to a semiconductor device.

### Solution to Problem

A cooler according to an aspect of the present invention includes: a top plate having a first face on which a dissipation face is formed; a bottom plate disposed counter to the top plate, the bottom plate being larger in thickness than the top plate; a plurality of fins connected to at least the top plate; a peripheral wall formed between the top plate and the bottom plate, the peripheral wall surrounding the outer periphery of the fins; a flow path for refrigerant formed in a space surrounded by the top plate, the bottom plate, the fins, and the peripheral wall; an inlet for the refrigerant provided to the top plate, the bottom plate, or the peripheral wall on one end side in a first direction of the flow path for the refrigerant; and an outlet for the refrigerant provided to the top plate, the bottom plate, or the peripheral wall on another end side in the first direction of the flow path for the refrigerant, in which the fins each include an inclined portion extending in a direction in which the inclined portion is displaced toward the inlet for the refrigerant as distanced from the first face of the top plate in first plan view when viewed in a second direction perpendicular to the first direction, the inclined portion extending in a direction in which the inclined portion is displaced in the second direction as distanced from the first face of the top plate in second plan view when viewed in the first direction.

### Advantageous Effects of Invention

According to the present invention, it is achievable to improve the cooling performance of a cooler applied to a semiconductor device.

### BRIEF DESCRIPTION OF DRAWINGS

FIG. 1 is a top view illustrating an exemplary configuration of a semiconductor device according to an embodiment.

FIG. 2 is an enlarged top view illustrating a configuration of a single-circuit formation part in the semiconductor device in FIG. 1.

FIG. 3 is a side sectional view illustrating the exemplary configuration of the semiconductor device taken along line A-A′ in FIG. 1.

FIG. 4 is a side sectional view illustrating the exemplary configuration of the semiconductor device taken along line B-B′ in FIG. 1.

FIG. 5 is a diagram illustrating an exemplary circuit configuration of an inverter with the semiconductor device in FIG. 1 applied thereto.

FIG. 6 is a bottom view illustrating a specific example of fins of the cooler according to the embodiment.

FIG. 7 is a view for explaining a first characteristic of refrigerant flow in the cooler according to the embodiment.

FIG. 8 is a view for explaining a second characteristic of refrigerant flow in the cooler according to the embodiment.

FIG. 9 is a graph indicating a relationship between the angle in the extending direction of a fin, the value of thermal resistance, and pressure drop.

FIG. 10 is a supplementary view regarding the angle in the extending direction and the disposition of fins.

FIG. 11 is a side sectional view for explaining a first modification of the configuration of the cooler.

FIG. 12 is a side sectional view for explaining a first modification of fin arrangement.

FIG. 13 is a side sectional view for explaining a second modification of the fin arrangement.

FIG. 14 is a side sectional view for explaining a third modification of the fin arrangement.

FIG. 15 is a side sectional view illustrating a second modification of the configuration of the cooler.

FIG. 16 is a side sectional view illustrating a third modification of the configuration of the cooler.

FIG. 17 is a side sectional view illustrating a fourth modification of the configuration of the cooler.

FIG. 18 is a view for explaining a fifth modification of the configuration of the cooler.

FIG. 19 is a view for explaining a sixth modification of the configuration of the cooler.

FIG. 20 is a bottom view for explaining a modification of the positional relationship between an inlet and an outlet for refrigerant in the cooler.

FIG. 21 is a side sectional view illustrating a first modification of the configuration of the cooler and the positional relationship between the inlet and outlet for refrigerant.

FIG. 22 is a side sectional view illustrating a second modification of the configuration of the cooler and the positional relationship between the inlet and the outlet for refrigerant.

FIG. 23 is a side sectional view illustrating a third modification of the configuration of the cooler and the positional relationship between the inlet and the outlet for refrigerant.

FIG. 24 is a schematic plan view illustrating an exemplary vehicle to which the semiconductor device according to the present invention is applied.

### DESCRIPTION OF EMBODIMENTS

Hereinafter, embodiments of the present invention will be described in detail with reference to the drawings. Note that an X-axis, a Y-axis, and a Z-axis in each of the drawings to be referred to are illustrated for the purpose of defining a plane and a direction in an exemplified semiconductor device, cooler, and others. The X-axis, the Y-axis, and the Z-axis are orthogonal to each other and define a right-handed system. In the following description, a direction parallel to the X-axis is referred to as an X direction, a direction parallel to the Y-axis is referred to as a Y direction, and a direction parallel to the Z-axis is referred to as a Z direction. In addition, in a case where each of the X direction, the Y direction, and the Z direction is associated with a direction indicated by an arrow (positive or negative) of the X-axis, the Y-axis, and the Z-axis illustrated, a “positive side” or a “negative side” is added.

In the present specification, the Z direction may be referred to as an up-and-down direction. In the present specification, “above (on)” and “upper (upward)” are intended to be on the positive side in the Z direction with respect to the reference face (or surface), member, or position, for example, and “below (under)” and “lower (downward)” are intended to be on the negative side in the Z direction with respect to the reference face, member, or position, for example. For example, when it is described that “the member B is disposed above the member A”, the member B is disposed on the positive side in the Z direction when viewed from the member A. Further, when “the upper face (upper surface) of the member A” is described, the face (surface) is located at the end of the member A on the positive side in the Z direction and faces the positive side in the Z direction. In the present specification, the term “top view” is intended as plan view when a target article (e.g., a semiconductor device or a cooler) is viewed from the positive side in the Z direction, and the term “bottom view” is intended as plan view when the target article is viewed from the negative side in the Z direction. In the present specification, the term “front view” is intended as plan view when the target article is viewed from the negative side in the Y direction. In the present specification, the term “side view” is intended as plan view when the target article is viewed from the negative side in the X direction or the positive side in the X direction, and the plan view when viewed from the negative side in the X direction may be referred to as “left side view”, and the plan view when viewed from the positive side in the X direction may be referred to as “right side view”. Such directions and faces (surfaces) are terms used for convenience of description. Thus, depending on, for example, an attachment posture of the semiconductor device, a correspondence relationship with directions of the X-axis, the Y-axis, and the Z-axis may vary. For example, a face (surface) of the cooler on which a wiring board and a semiconductor element are disposed is referred to as an upper face (upper surface) of the cooler in the present specification, but is not limited thereto, and may be referred to as, for example, a lower face (lower surface), or a side face (side surface) of the cooler. In addition, an aspect ratio and a size relationship between the members in each drawing are merely schematically represented, and thus do not necessarily coincide with a relationship in, for example, the semiconductor device or the cooler actually manufactured. For convenience of description, it is also assumed that the size relationship between the members might be exaggerated.

Further, a semiconductor device to be exemplified in the following description may be applied to, for example, an electric power convertor such as an inverter for an industrial component or electrical/electronic component (e.g., an in-vehicle motor). Thus, in the following description, detailed description of the same or similar configuration, function, operation, manufacturing method, and others as those of the known semiconductor device will not be given.

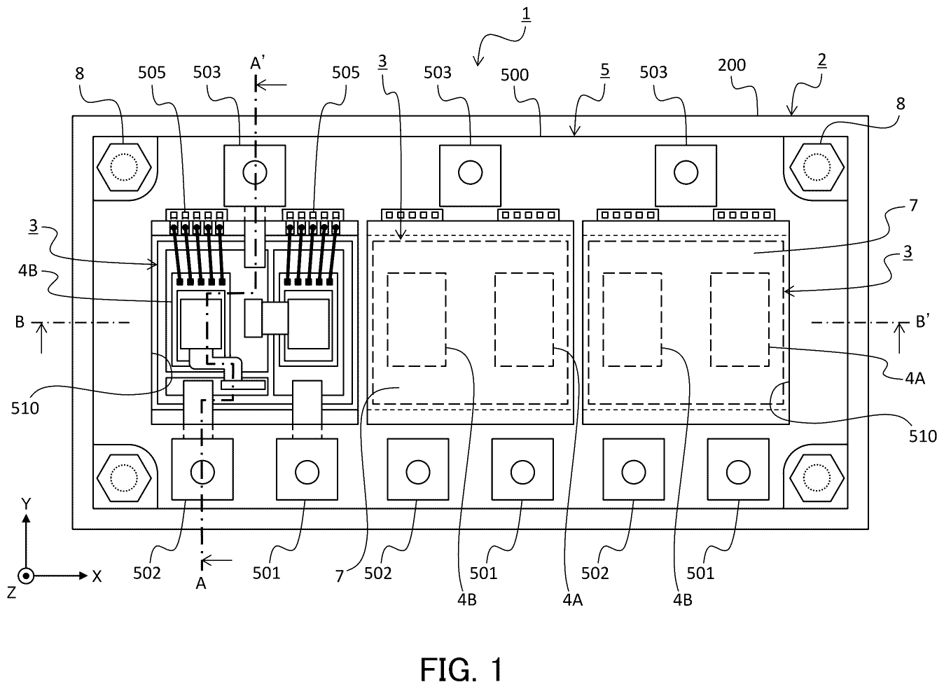

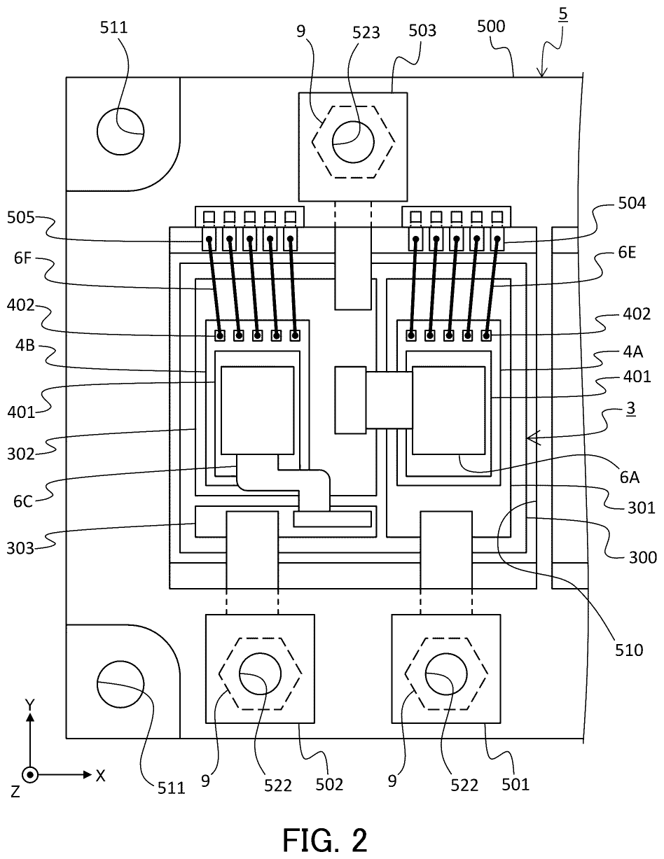

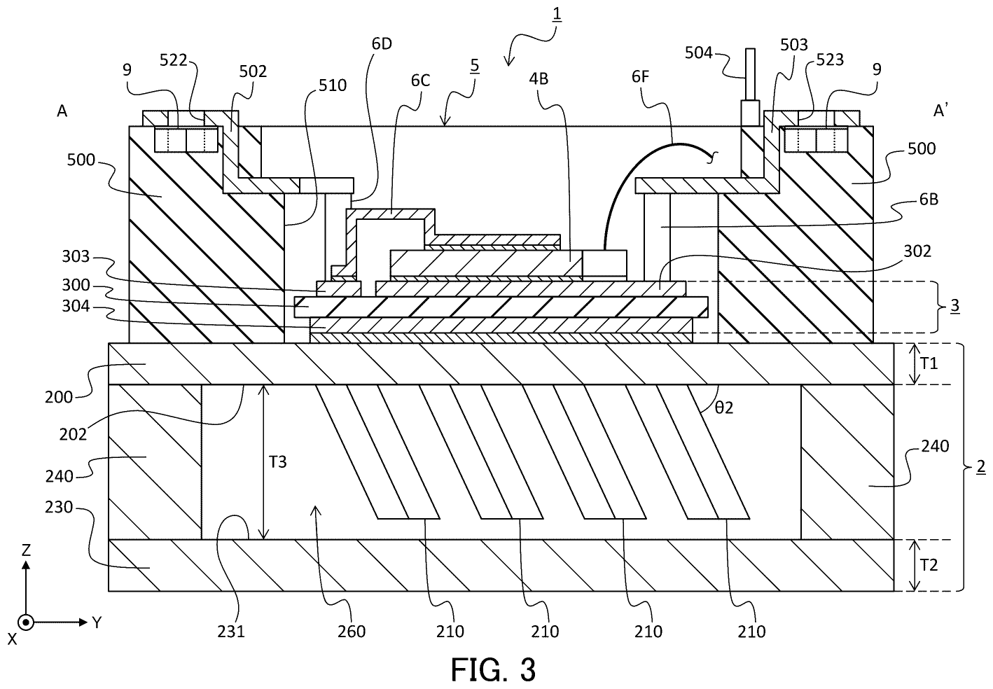

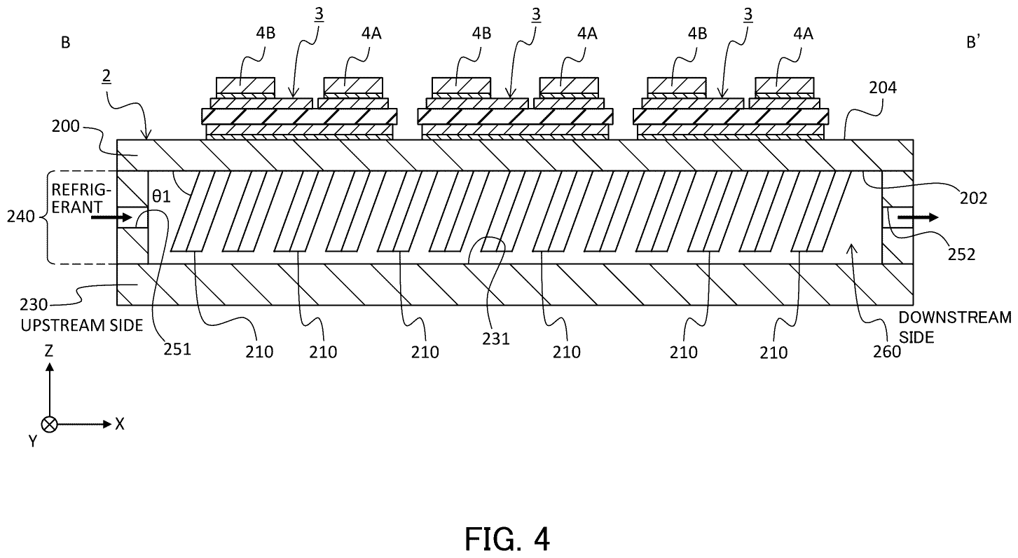

FIG. 1 is a top view illustrating an exemplary configuration of a semiconductor device according to an embodiment. FIG. 2 is an enlarged top view illustrating a configuration of a single-circuit formation part in the semiconductor device in FIG. 1. FIG. 3 is a side sectional view illustrating the exemplary configuration of the semiconductor device taken along line A-A′ in FIG. 1. FIG. 4 is a side sectional view illustrating the exemplary configuration of the semiconductor device taken along line B-B′ in FIG. 1. The side sectional view of FIG. 3 illustrates, in right side view, a portion on the left of line A-A′ of the semiconductor device taken along line A-A′ in FIG. 1. The side sectional view of FIG. 4 illustrates, in front view, a portion above line B-B′ of the semiconductor device taken along line B-B′ in FIG. 1. Note that illustration of a sealing material for sealing, for example, a semiconductor element is not given in FIGS. 2 and 3, and illustration of a lead, a case, the sealing material, and others are not given in FIG. 4.

A semiconductor device 1 illustrated in FIGS. 1 to 4 includes a cooler 2, a wiring board 3, semiconductor elements 4A and 4B, a case 5, wiring components 6A to 6F, and a sealing material 7.

In the cooler 2, a flow path 260 for refrigerant for dissipating heat generated from the semiconductor elements 4A and 4B of the semiconductor device 1 is formed, and is connected to a circulation circuit for circulating the refrigerant. The flow path 260 for refrigerant of the cooler 2 is defined by a top plate 200, a bottom plate 230, and a peripheral wall 240. The top plate 200 has a substantially rectangular outer shape in top view, and has a lower face (heat dissipation face or surface) 202 on which a plurality of fins 210 extending downward from the lower face 202 is disposed. The peripheral wall 240 has a quadrangular ring shape as plane shape in top view and surrounds the outer periphery of the fins 210. The peripheral wall 240 is disposed under the top plate 200 such that an upper opening end of the peripheral wall 240 is covered with the top plate 200. The bottom plate 230 is disposed under the peripheral wall 240 to cover a lower opening end of the peripheral wall 240. In the cooler 2, the relationship between the thickness T1 of the top plate 200 and the thickness T2 of the bottom plate 230 disposed counter to the top plate 200 can satisfy T2>T1 as illustrated in FIGS. 3 and 4. Further, the thickness T3 of the peripheral wall 240 can satisfy T3>T2.

The top plate 200, the peripheral wall 240, and the bottom plate 230 illustrated in FIGS. 3 and 4 are integrated such that an upper face of the peripheral wall 240 is in close contact with the lower face 202 of the top plate 200 and a lower face of the peripheral wall 240 is in close contact with an upper face 231 of the bottom plate 230. A method of integrating the top plate 200, the peripheral wall 240, and the bottom plate 230 is not limited to a specific method. Further, in the cooler 2 illustrated in FIGS. 3 and 4, the peripheral wall 240 includes an inlet 251 through which refrigerant flows into the flow path 260 for refrigerant and an outlet 252 through which the refrigerant is discharged from the flow path 260 for refrigerant. The outlet 252 may be referred to as an outflow port through which the refrigerant flows out. A specific description of the configuration and others of the cooler 2 will be given later.

In the semiconductor device 1 illustrated in FIG. 1, three wiring boards 3 are disposed above the top plate 200 of the cooler 2. The three wiring boards 3 are substantially the same in configuration, and each include an insulating substrate 300, conductor patterns 301 to 303 provided on an upper face of the insulating substrate 300, and a conductor pattern 304 provided on a lower face of the insulating substrate 300. Such a wiring board 3 as described above may be, for example, a direct copper bonding (DCB) substrate or an active metal brazing (AMB) substrate. The wiring board 3 may be referred to as a laminated substrate or an insulating circuit board, for example.

The insulating substrate 300 is not limited to a specific substrate. The insulating substrate 300 may be, for example, a ceramic substrate made of a ceramic material such as a composite material containing aluminum oxide (Al₂O₃), aluminum nitride (AlN), silicon nitride (Si₃N₄), or aluminum oxide (Al₂O₃), and zirconium oxide (ZrO₂). The insulating substrate 300 may be, for example, a substrate resulting from molding an insulating resin such as epoxy resin, a substrate resulting from impregnating a base material such as a glass fiber with an insulating resin, or a substrate resulting from coating the surface of a flat-plate shaped metal core with an insulating resin.

The conductor pattern 304 provided on the lower face of the insulating substrate 300 functions as a thermally conductive member that conducts, to the cooler 2, heat generated from the semiconductor elements 4A and 4B, and is formed of, for example, a metal plate or a metal foil such as copper or aluminum. The conductor pattern 304 is joined to an upper face 204 of the top plate 200 of the cooler 2 by a joining material (not illustrated) such as solder. The conductor pattern 304 may be referred to as a heat dissipation layer or a heat dissipation pattern. For example, the wiring board 3 may be disposed such that the conductor pattern 304 is joined to a base plate different from the top plate 200 to conduct heat to the top plate 200 through the base plate.

The conductor patterns 301 to 303 provided on the upper face of the insulating substrate 300 each function as a wiring component, and are each formed of, for example, a metal plate or a metal foil such as copper or aluminum. The conductor patterns 301 to 303 provided on the upper face of the insulating substrate 300 may be referred to as conductor layers, conductor plates, conductive layers, or wiring patterns, for example. In the following description, when the conductor patterns 301 to 303 are distinguished from each other, the conductor pattern 301, the conductor pattern 302, and the conductor pattern 303 are respectively written as a first conductor pattern 301, a second conductor pattern 302, and a third conductor pattern 303.

The semiconductor element 4A is disposed on an upper face of the first conductor pattern 301. The first conductor pattern 301 is joined to a first main electrode (not illustrated) provided on a lower face of the semiconductor element 4A by a joining material (not illustrated). The joining material is a known joining material such as solder. Further, the semiconductor element 4B is disposed on an upper face of the second conductor pattern 302. The second conductor pattern 302 is joined to a first main electrode (not illustrated) provided on a lower face of the semiconductor element 4B by a joining material (not illustrated).

The semiconductor element 4A and the semiconductor element 4B are each formed of, for example, a reverse conducting (RC)-insulated gate bipolar transistor (IGBT) element having a function corresponding to a combination of the function of an IGBT element as a switching element and the function of a diode element such as a free wheeling diode (FWD) element connected to the switching element in an inverse parallel manner. Each of this type of semiconductor elements 4A and 4B has the lower face on which the first main electrode is provided and an upper face on which a second main electrode and a control electrode (gate electrode) are provided. When the switching element of each of the semiconductor elements 4A and 4B is an IGBT element, the first main electrode on the lower face side may be referred to as a collector electrode, and the second main electrode on the upper face side may be referred to as an emitter electrode.

The first main electrode provided on the lower face of the semiconductor element 4A is electrically connected to a first main terminal 501 provided to the case 5, through the first conductor pattern 301. The first conductor pattern 301 and the first main terminal 501 are electrically connected by a known method. For example, the first conductor pattern 301 and the first main terminal 501 are electrically connected through a columnar or block-shaped wiring component (not illustrated) extending upward from the upper face of the first conductor pattern 301. A second main electrode 401 provided on the upper face of the semiconductor element 4A is electrically connected to a third main terminal 503 provided to the case 5, through the wiring component 6A and the second conductor pattern 302. The wiring component 6A is formed by bending a conductor plate such as a copper plate, and is called, for example, a lead or a lead frame. The wiring component 6A is joined to the second main electrode 401 of the semiconductor element 4A and the second conductor pattern 302 by a bonding material (not illustrated). Further, in the example of FIG. 2, the second conductor pattern 302 and the third main terminal 503 are electrically connected through a columnar conductive member (wiring component 6B) extending upward from the upper face of the second conductor pattern 302. The second conductor pattern 302 and the third main terminal 503 are electrically connected by another known method. The control electrode 402 provided on the upper face of the semiconductor element 4A is electrically connected to a control terminal 504 provided to the case 5 by a bonding wire (wiring component 6E).

The first main electrode provided on the lower face of the semiconductor element 4B is electrically connected to the third main terminal 503 provided to the case 5, through the second conductor pattern 302 and the wiring component 6B. The second main electrode 401 provided on the upper face of the semiconductor element 4B is electrically connected to a second main terminal 502 provided to the case 5, through the wiring component 6C and the third conductor pattern 303. The wiring component 6C is formed by bending a conductor plate such as a copper plate, and is called, for example, a lead or a lead frame. The wiring component 6C is joined to the second main electrode 401 of the semiconductor element 4B and the third conductor pattern 303 by a joining material (not illustrated). Further, in the example of FIG. 2, the third conductor pattern 303 and the second main terminal 502 are electrically connected through a columnar conductive member (wiring component 6D) extending upward from the upper face of the third conductor pattern 303. The control electrode 402 provided on the upper face of the semiconductor element 4B is electrically connected to a control terminal 505 provided to the case 5 by a bonding wire (wiring component 6F).

The case 5 has an upper end and a lower end that are each opened, and includes, for example, an insulating member 500 having a hollow portion 510 capable of accommodating the wiring boards 3, the semiconductor elements 4A and 4B, and the wiring components 6A to 6F, the first main terminals 501, the second main terminals 502, the third main terminals 503, the control terminals 504, and the control terminals 505 described above. Respective ends of the first main terminals 501, the second main terminals 502, the third main terminals 503, the control terminals 504, and the control terminals 505 are exposed in the hollow portion 510 of the insulating member 500, and the other ends of the first main terminals 501, the second main terminals 502, the third main terminals 503, the control terminals 504, and the control terminals 505 protrude from an upper face of the insulating member 500. The respective portions of the first main terminals 501, the second main terminals 502, and the third main terminals 503 protruding from the upper face of the insulating member 500 are bent to extend along the upper face of the insulating member 500. A region overlapping each first main terminal 501, a region overlapping each second main terminal 502, and a region overlapping each third main terminal 503 on the upper face of the insulating member 500 are each provided with a recess in which a nut 9 is fitted. The first main terminal 501, the second main terminal 502, and the third main terminal 503 are, respectively, provided with a through hole 521, a through hole 522, and a through hole 523 corresponding one-to-one to the screw holes of the nuts 9 fitted in the recesses formed in the upper face of the insulating member 500. The nuts 9 are used to screw the bolts for connecting one-to-one the first main terminal 501, the second main terminal 502, and the third main terminal 503 to, for example, a terminal of a power supply cable such as a wire harness or a power supply component such as a bus bar.

The hollow portion 510 of the case 5 is filled with the sealing material 7 for sealing the wiring boards 3, the semiconductor elements 4A and 4B, the wiring components 6A to 6F, and others. The sealing material 7 is an epoxy resin or a silicone gel, for example. The hollow portion 510 of the case 5 may be formed as a single hollow portion without being divided for each wiring board 3 (i.e., without being divided into three separate hollow portions) as illustrated in FIG. 1.

For example, as illustrated in FIG. 2, in the case 5, through holes 511 are provided one-to-one at positions corresponding to the corners of the case 5 in top view. The case 5 is attached to the top plate 200 of the cooler 2 by, for example, screwing bolts 8 inserted one-to-one in the through holes 511 into the corresponding screw holes provided in the top plate 200 of the cooler 2. The positions and the number of through holes 511 for attaching the case 5 to the top plate 200 are not limited to the positions and the number illustrated in FIG. 2. Further, a method of attaching the case 5 to the top plate 200 is not limited to a specific method.

The semiconductor device 1 illustrated in FIG. 1 includes three single-phase inverter circuits, and can constitute, for example, a three-phase inverter.

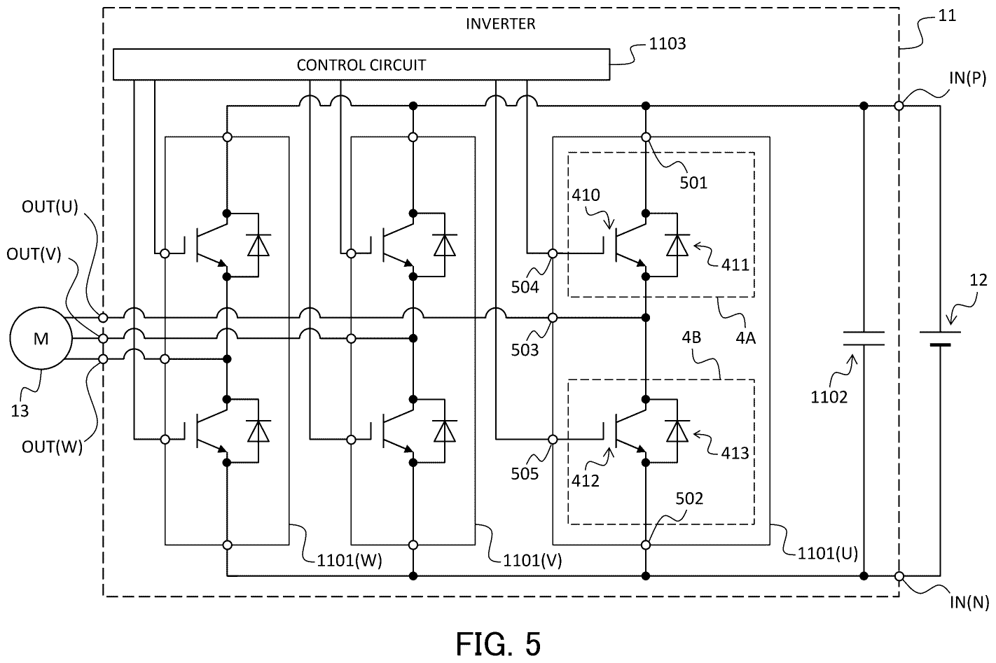

FIG. 5 is a diagram illustrating an exemplary circuit configuration of an inverter with the semiconductor device in FIG. 1 applied thereto.

In FIG. 5, as an example of an inverter 11, a circuit configuration of a three-phase voltage source inverter is exemplarily illustrated. The inverter 11 includes three single-phase inverter circuits 1101(U), 1101(V), and 1101(W), a smoothing capacitor 1102, and a control circuit 1103. Such a single-phase inverter circuit includes one wiring board 3 and two semiconductor elements 4A and 4B. The single-phase inverter circuit 1101(U) converts a direct current into an alternating current and outputs the alternating current as a U-phase alternating current. The single-phase inverter circuit 1101(V) converts a direct current into an alternating current and outputs the alternating current as a V-phase alternating current. The single-phase inverter circuit 1101(W) converts a direct current into an alternating current and outputs the alternating current as a W-phase alternating current. In the present specification, although three phases in the three-phase alternating current are referred to as a U phase, a V phase, and a W phase, the three phases may be referred to as other terms.

In the inverter 11, the three single-phase inverter circuits 1101(U), 1101(V), and 1101(W), and the smoothing capacitor 1102 are connected in parallel. The circuit configuration of each of the three single-phase inverter circuits 1101(U), 1101(V), and 1101(W) exemplified as equivalent circuits in FIG. 5 corresponds to the circuit including the one wiring board 3 and the two semiconductor elements 4A and 4B in the semiconductor device 1 described above with reference to FIGS. 2 and 3.

The inverter 11 includes a first input end IN(P) that is connected to a positive electrode of a direct current power supply 12, a second input end IN(N) that is connected to a negative electrode of the direct current power supply 12, and output ends OUT(U), OUT(V), and OUT(W) for outputting three-phase alternating current.

Each of the single-phase inverter circuits 1101(U), 1101(V), and 1101(W) illustrated in FIG. 5 is a half-bridge inverter circuit. In the single-phase inverter circuit 1101(U), the collector electrode of a switching element 410 (e.g., an IGBT element) of the semiconductor element 4A that may be referred to as an upper arm and is connected between the first input end IN(P) and the output end OUT(U) is connected to the first input end IN(P) through the first main terminal 501. Further, in the single-phase inverter circuit 1101(U), the emitter electrode of a switching element 412 of the semiconductor element 4B that may be referred to as a lower arm and is connected between the second input end IN(N) and the output end OUT(U) is connected to the second input end IN(N) through the second main terminal 502. The emitter electrode of the switching element 410 of the upper arm and the collector electrode of the switching element 412 of the lower arm in the single-phase inverter circuit 1101(U) are connected through the third main terminal 503 to the output end OUT(U) for outputting the U-phase alternating current in the three-phase alternating current. In addition, a diode element 411 is connected in reverse parallel to the switching element 410 of the upper arm, and a diode element 413 is connected in reverse parallel to the switching element 412 of the lower arm. The other single-phase inverter circuits 1101(V) has a configuration in which the output end OUT(U) of the single-phase inverter circuit 1101(U) described above is replaced with the output ends OUT(V), and the other single-phase inverter circuit 1101(V) has a configuration in which the output end OUT(U) of the single-phase inverter circuit 1101(U) described above is replaced with output end OUT(V).

The alternating current output from each of the single-phase inverter circuits 1101(U), 1101(V), and 1101(W) is controlled by a control signal applied from the control circuit 1103 to the gate of the switching element 410 of the upper arm (the control electrode 402 of the semiconductor element 4A) through the control terminal 504 and a control signal applied to the gate of the switching element 412 of the lower arm (the control electrode 402 of the semiconductor element 4B) through the control terminal 505 such that the phases are shifted from each other by 120 degrees. The output ends OUT(U), OUT(V), and OUT(W) of the inverter 11 are connected to a load (e.g., an AC motor) 13 that operates with an alternating current.

Note that the circuit configuration of the inverter 11 including the semiconductor device 1 of the present embodiment is not limited to the circuit configuration illustrated in FIG. 5. In addition, the operation of the inverter 11 including the semiconductor device 1 of the present embodiment is not limited to a specific operation. For example, in the inverter 11 including the semiconductor device 1, three single-phase full-bridge inverter circuits may be connected in parallel.

Further, the inverter 11 described above with reference to FIG. 5 is merely an example of an apparatus to which the semiconductor device 1 according to the present embodiment is applied.

The switching elements 410 and 412 of the semiconductor elements 4A and 4B are not limited to the IGBT elements described above, and thus may each include, for example, a power metal oxide semiconductor field effect transistor (MOSFET) or a bipolar junction transistor (BJT). When such a switching element is a MOSFET element, the main electrode on the lower face side of each of the semiconductor elements 4A and 4B may be referred to as a drain electrode, and the main electrode on the upper face side may be referred to as a source electrode. In addition, the diode elements 411 and 413 may each include, for example, a schottky barrier diode (SBD), a junction barrier schottky (JBS) diode, a merged PN schottky (MPS) diode, or a PN diode. Further, the control electrodes 402 provided on the upper faces of the semiconductor elements 4A and 4B may each include a gate electrode and an auxiliary electrode. For example, the auxiliary electrode may be an auxiliary emitter electrode or an auxiliary source electrode that is electrically connected to the main electrode on the upper face side and serves as a reference potential to a gate potential. Alternatively, the auxiliary electrode may be a temperature sensing electrode electrically connected to a temperature sensing unit that may be included in for example, the inverter 11, for measuring the temperatures of the semiconductor elements 4A and 4B. These electrodes (the second main electrode 401 and the control electrode 402 that includes the gate electrode and the auxiliary electrode) formed on each of the upper faces of the semiconductor elements 4A and 4B may be collectively referred to as an upper face electrode. Further, the substrate on which the switching elements 410 and 412 and the diode elements 411 and 413 are formed is not limited to a silicon substrate, and may be, for example, a silicon carbide (SiC) substrate or a gallium nitride (GaN) substrate.

In addition, the switching element and the diode element described as being included in one semiconductor element in the single-phase inverter circuit described above with reference to FIG. 5 may be provided by separate semiconductor elements. For example, the switching element 410 and the diode element 411 of the upper arm may be provided by a semiconductor element with the switching element 410 formed therein and a semiconductor element with the diode element 411 formed therein. The shape, disposition number, disposition location, and others of each semiconductor element can appropriately be changed. The layout of the conductor patterns as the wiring components provided on the upper face side of the wiring board 3 is changed in accordance with the type, shape, disposition number, disposition location, and others of the semiconductor element.

As described above with reference to FIGS. 3 and 4, for example, the cooler 2 in the semiconductor device 1 according to the present embodiment may include the top plate 200 with the fins 210 disposed on the lower face 202, the bottom plate 230, and the peripheral wall 240. In the cooler 2 exemplified in the present embodiment, the inlet 251 for refrigerant is provided to the left side face and the outlet 252 for refrigerant is provided to the right side face in top view (FIG. 1) and front view (FIG. 4). In other words, the flow path 260 for refrigerant of the cooler 2 defined by the top plate 200, the bottom plate 230, and the peripheral wall 240 has the left side face as an upstream end and the right side face as a downstream end. The number of single-phase inverter circuits (sets of wiring board 3 and semiconductor elements 4A and 4B) disposed above the top plate 200 of the single cooler 2 is not limited to three. Further, such a single-phase inverter circuit as described above and a circuit different from the single-phase inverter circuit may be disposed above the top plate 200.

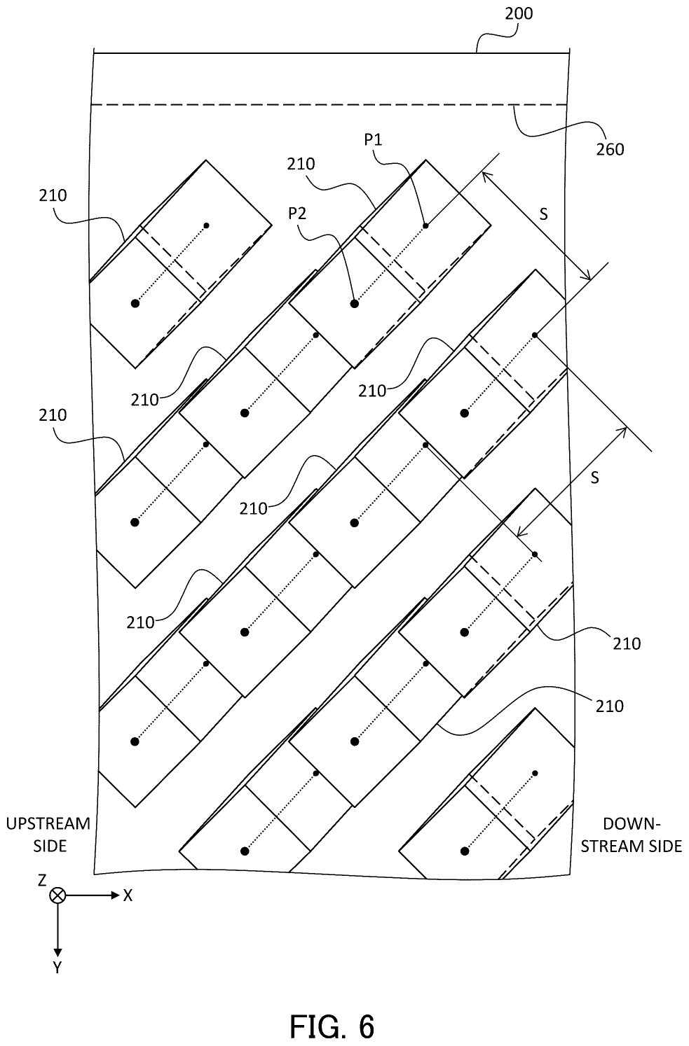

As will be described later with reference to FIG. 6, each of fins 210 is a fin sometimes referred to as a pin fin having a columnar outer shape, and is disposed in a two-dimensional lattice shape on the lower face 202 of the top plate 200. The top plate 200 with the fins 210 disposed thereon is a member that dissipates heat conducted from the semiconductor elements 4A and 4B through the wiring board 3, and is formed of, for example, an aluminum alloy. The fins 210 of the cooler 2 according to the present embodiment each has an extending direction that is non-parallel to a normal direction (Z direction) of the lower face 202 in front view (FIG. 4) and side view (FIG. 3). More specifically, each of the fins 210 extends and is displaced to the upstream side of the flow path 260 for refrigerant as distanced from the lower face 202 of the top plate 200 in front view (FIG. 4) and is displaced to the end face side in the horizontal direction of the flow path 260 for refrigerant as distanced from the lower face 202 of the top plate 200 in side view (FIG. 3) (in other words, the distance from the peripheral wall 240 changes). The angle θ1 on the acute angle side in the extending direction of each fin 210 in front view (hereinafter, simply referred to as “angle (first angle) θ1”) and the angle θ2 on the acute angle side in the extending direction of the fin 210 of in side view (hereinafter, simply referred to as “angle (second angle) θ2”) may be the same or different in value. In other words, the angle θ1 is an angle formed between the direction X and a projection of the extending direction of each inclined portion onto a plane (first plane) that contains the direction X and is orthogonal to the heat dissipation surface as shown in FIG. 4. The angle θ2 is an angle formed between the direction Y and a projection of the extending direction of each inclined portion onto a plans (second plane) that contains the direction Y and is orthogonal to the heat dissipation surface as shown in FIG. 3.

FIG. 6 is a bottom view for explaining a specific example of such fins as described above of the cooler according to the embodiment.

For example, as illustrated in FIG. 6, each of the fins 210 of the cooler 2 according to the present embodiment has an inclined columnar outer shape, and is disposed in a two-dimensional lattice shape having an interval D1 between the fins 210 adjacent in a direction at an angle of 45 degrees to respective extending directions (X direction and Y direction) of the sides on the lower face 202 of the top plate 200. The “inclined columnar shape” in the present specification means a columnar shape in which the center P1 of the end surface (end surface at a first end of the inclined portion) on the lower face 202 side of the top plate 200 and the center P2 of the end face (end surface at a second end of the inclined portion) farthest from the lower face 202 in the extending direction of each fin 210 do not coincide with each other in plan view (bottom view).

The fins 210 exemplified in FIG. 6 each have a first bottom face (and a second bottom face) that is square in shape, and is disposed such that the first bottom face has sides each having an extending direction at an angle of 45 degrees to the extending direction of the corresponding side of the fin 210 on the lower face 202 of the top plate 200. In other words, the fins 210 are each disposed such that the extending directions of the sides of the first bottom face at an angle of 45 degrees to the direction (X-axis direction) from the inlet 251 for refrigerant (upstream side) toward the outlet 252 for refrigerant (downstream side).

Such a top plate 200 on which a plurality of fins 210 each having an inclined columnar shape is disposed in a two-dimensional lattice pattern as illustrated in FIG. 6 can be manufactured by applying a known method. For example, the surface of a metal material is cut by simultaneously using a plurality of blades, so that a top plate 200 having a plurality of fins 210 each having an inclined columnar shape can be manufactured. Alternatively, a top plate 200 having a plurality of fins 210 each having an inclined columnar shape can be manufactured using, for example, a molding method called metal injection molding (MIM). Further, a top plate 200 having a plurality of fins 210 each having an inclined columnar shape can be manufactured with, for example, a 3D printer. The method of manufacturing the top plate 200 having the fins 210 each having an inclined columnar shape is not limited to the above-described manufacturing methods.

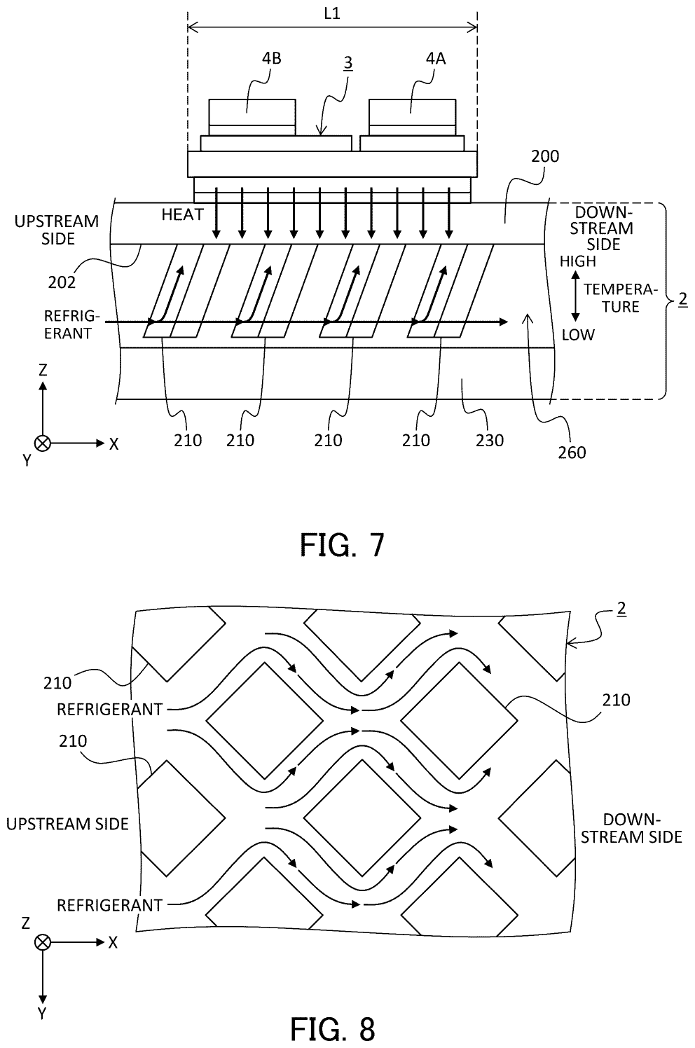

The operation and effect resulting from application of the cooler 2 according to the present embodiment will be described with reference to FIGS. 7 to 10.

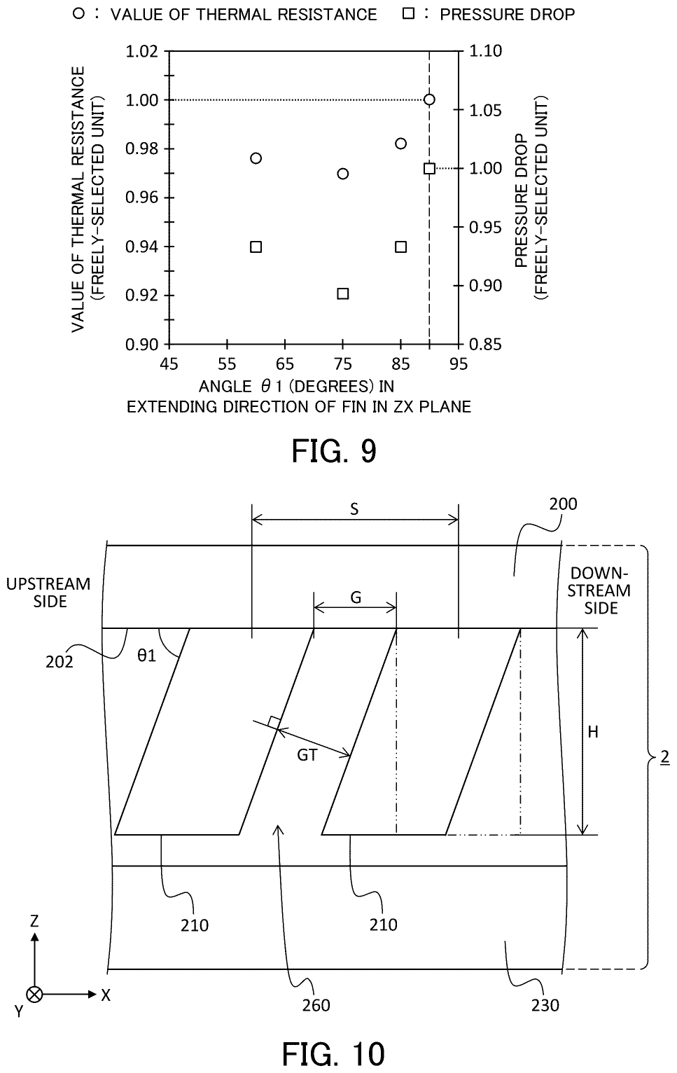

FIG. 7 is a view for explaining a first characteristic of refrigerant flow in the cooler according to the embodiment. FIG. 8 is a view for explaining a second characteristic of refrigerant flow in the cooler according to the embodiment. FIG. 9 is a graph indicating a relationship between the angle in the extending direction of a fin, the value of thermal resistance, and pressure drop. FIG. 10 is a supplementary view regarding the angle in the extending direction and the disposition of fins.

In the cooler 2 according to the present embodiment, as illustrated in FIG. 7, each of the fins 210 extending downward from the lower face 202 of the top plate 200 has an inclined columnar outer shape that is displaced to the upstream side of the flow path 260 for refrigerant as a portion of the fin 210 is distanced from the top plate 200. In operation of the semiconductor device 1 according to the present embodiment, part of heat generated from the semiconductor elements 4A and 4B disposed above the top plate 200 is conducted to the top plate 200 of the cooler 2 through the wiring board 3, and is dissipated by heat exchange between the fins 210 and the refrigerant flowing through the flow path 260. Because the heat exchange between the fins 210 and the refrigerant is more active at a position closer to a heat source (heating element), the refrigerant flowing through the flow path 260 defined in the cooler 2 tends to have a higher temperature in the upper layer portion closer to the semiconductor elements 4A and 4B each as a heat source (heating element) than in the lower layer portion. An increase in the temperature of the refrigerant in the upper layer portion of the flow path 260 causes a decrease in the efficiency of heat exchange between the fins 210 and the refrigerant, so that the cooling performance decreases.

For this disadvantage, as described above, the fins 210 of the cooler 2 according to the present embodiment each have an inclined columnar outer shape that is displaced to the upstream side as the portion of the fin 210 is distanced from the top plate 200. In other words, the fins 210 each have an inclined side face that is displaced to the downstream side as a portion of the fin 210 is closer to the lower face 202 of the top plate 200. With this arrangement, as illustrated in FIG. 7, part of the refrigerant flowing from upstream to downstream in the flow path 260 of the cooler 2 is guided to the upper layer side of the flow path 260 along the inclined side face of the fin 210. In addition, as illustrated in FIG. 3, the fins 210 of the cooler 2 according to the present embodiment each have an inclined columnar outer shape inclined in a direction in which the extending direction of the fin 210 is non-parallel to the normal direction of the lower face 202 of the top plate 200 also in side view. Therefore, of the refrigerant flowing through the flow path 260 of the cooler 2 from upstream to downstream, the refrigerant flowing through the portion closer to both end sides in the horizontal direction (the left end and the right end of the flow path 260 of FIG. 3) in side view can be guided to the central portion in the horizontal direction along the inclined side face of the fin 210. With this arrangement, the refrigerant relatively lower in temperature flowing through the lower layer portion of the flow path 260 and the end portion where heat from the wiring board 3 is difficult to conduct and the refrigerant relatively higher in temperature in the upper layer portion of the flow path 260 can be stirred, which results in prevention of an increase of the temperature of the refrigerant in the upper layer portion of the flow path 260. Therefore, a decrease in the efficiency of heat exchange between the fins 210 and the refrigerant in the upper layer portion of the flow path 260 can be effectively prevented, whereby the cooling performance can be improved. Further, the improvement of the cooling performance enables reduction of a contact area (size L1) between the wiring board 3 and the top plate 20 for conducting a predetermined amount of heat from the wiring board 3 to the cooler 2, whereby the wiring board 3 can be downsized and the semiconductor device 1 can be downsized.

In addition, as illustrated in FIG. 8, when each of the fins 210 has a first bottom face that is square in shape and has sides each having an extending direction, in a case where the respective extending directions of the sides of the first bottom face are inclined by an angle of 45 degrees to the direction from upstream to downstream in the flow path for the refrigerant, the refrigerant flowing from upstream to downstream repeats branching and joining along the side face inclined to the fins 210 as indicated by an arrow in FIG. 8, for example. Due to such branching and joining of the refrigerant in plan view (bottom view) and the stirring of the refrigerant described above with reference to FIG. 7 in the refrigerant flowing through the flow path 260 of the cooler 2, for example, the stagnation of the refrigerant in the portion along the face facing downstream among the side faces of each fin 210 is reduced, so that the refrigerant increased in temperature by heat exchange can be smoothly guided to the outlet 252 located downstream. That is, the cooler 2 according to the present embodiment can also reduce pressure drop by reducing the stagnation of the refrigerant.

An example of the effects on the cooling performance and pressure drop by the cooler 2 according to the present embodiment is indicated in the graph of FIG. 9. The horizontal axis in the graph of FIG. 9 represents the angle θ1 (degree as unit) of the extending direction of a fin 210 in the ZX plane (front view). In the graph of FIG. 9, the left vertical axis represents the value of thermal resistance (freely-selected unit) associated with the cooling performance, and the right vertical axis represents pressure drop (freely-selected unit).

The graph of FIG. 9 indicates, as one of the conventional examples, the value of thermal resistance and pressure drop at the angle θ1 of 90 degrees in the extending direction of the fin 210. The value of thermal resistance and pressure drop at the angle θ1 in the graph of FIG. 9 that is set to 85 degrees, 75 degrees, and 60 degrees are examples of measurement values when the disposition interval S, the gap G, and the height H (see FIG. 10) of the fin 210 are, respectively, set to be the same as the disposition interval S, the gap G, and the height H of the fin when the angle θ1 is set to 90 degrees and only the angle θ1 is changed.

As can be seen from the graph of FIG. 9, the angle θ1 in the extending direction of the fin 210 to the direction (−X direction) toward the upstream of the flow path 260 in front view is set to less than 90 degrees, so that the value of thermal resistance and pressure drop are reduced as compared with the conventional example. In addition, although not indicated in the graph of FIG. 9, when the angle θ1 is set to less than 45 degrees, the inclination in the extending direction of the fin 210 to the flow path 260 for refrigerant increases, and for example, the effect of guiding the refrigerant in the lower layer portion of the flow path 260 to the upper layer portion is reduced. Further, when the angle θ1 is set to less than 45 degrees, the amount of shift of the center P2 of the second bottom face from the center P1 of the first bottom face described above with reference to FIG. 6 is larger, and for example, when the number of fins 210 is not changed as compared with the conventional example, the flow path 260 for accommodating the fins 210 is larger (i.e., the cooler 2 is larger). On the other hand, when the size of the flow path 260 is not changed as compared with the conventional example, the number of fins 210 is reduced, thereby resulting in reduction of the efficiency of heat exchange. Therefore, the angle θ1 in the extending direction of each fin 210 to the direction toward the upstream of the flow path 260 in front view is preferably set to 45 degrees or more and less than 90 degrees. In particular, from the graph of FIG. 9, it can be estimated that the angle θ1 is more preferably set to 60 degrees or more and 75 degrees or less.

In addition, as illustrated in FIG. 10, when the fin of which the angle θ1 is 90 degrees in the conventional example (two-dot chain line) is the same in the disposition interval S and the size of the bottom face as each fin 210 of which the angle θ1 is less than 90 degrees (solid line), the gap GT in the direction perpendicular to the side faces of the fins 210 each of which the angle θ1 is less than 90 degrees is shorter than the gap G in the direction parallel to the lower face 202 of the top plate 200 (T>GT). Therefore, under the conditions as the disposition interval S and the size of the bottom face of each fin 210 being the same as those in the conventional example in which the angle θ1 is 90 degrees, when the angle θ1 of the fin 210 is set to less than 90 degrees, the flow velocity of the refrigerant flowing from the lower layer portion toward the upper layer portion of the flow path 260 along the inclined side face of the fin 210 is increased, whereby the refrigerant in the lower layer portion and the refrigerant in the upper layer portion can be effectively stirred.

In addition, when the fin of which the angle θ1 is 90 degrees in the conventional example is the same in the height H and the size of the bottom face as the fin 210 of which the angle θ1 is set to less than 90 degrees, the area of the side face is larger when the angle θ1 is set to less than 90 degrees. Thus, under the conditions as the height H and the size of the bottom face of each fin 210 being the same as those in the conventional example in which the angle θ1 is 90 degrees, when the angle θ1 of the fin 210 is set to less than 90 degrees, whereby the efficiency of heat exchange per fin 210 can be improved. Therefore, for example, when the disposition interval (number) of the fins 210 is the same as that in the conventional example in which the angle θ1 is 90 degrees, the cooling performance is improved. In addition, because the number of fins 210 required to achieve the cooling performance at the same level as the conventional example in which the angle θ1 is 90 degrees can be reduced, whereby, for example, it is easy to manufacture the top plate 200 with the fins 210 disposed thereon. Further, in the case where the metal injection molding or the 3D printer described above is used to manufacture the top plate 200 with the fins 210 disposed thereon, the number of fins 210 is reduced, whereby for example, the amount of a material required for manufacturing the top plate 200 can be reduced, which is advantageous for reducing the manufacturing cost.

Note that the shape of each fin 210 of the cooler 2 according to the above-described embodiment is not limited to the inclined columnar outer shape in which the first bottom face and the second bottom face are square in shape as described above with reference to FIGS. 6 and 8, and may be another outer shape. For example, the first bottom face and the second bottom face of the fin 210 may each have a diamond shape, another polygon shape, a circle shape, or an ellipse (oval) shape. In addition, the fin 210 may have an outer shape in which the shapes of the first bottom face and the second bottom face are different, for example, in which the first bottom face is circular in shape and the second bottom face is square in shape. For example, the fin 210 may have an outer shape in which the first bottom face and the second bottom face have the same shape and at least one of the orientation and the size is different. Specifically, for example, the fin 210 may have, as an outer shape, the first bottom face and the second bottom face that are square in shape and may get thicker or thinner from the lower face 202 of the top plate 200 toward the bottom plate 230, or the fin 210 may have an outer shape twisted at the axis passing through the center P1 of the first bottom face and the center P2 of the second bottom face. Further, in the fin 210, for example, a portion extending in the normal direction of the lower face 202 may be present between the lower face 202 of the top plate 200 and a portion (inclined portion) having the above-described inclined columnar outer shape.

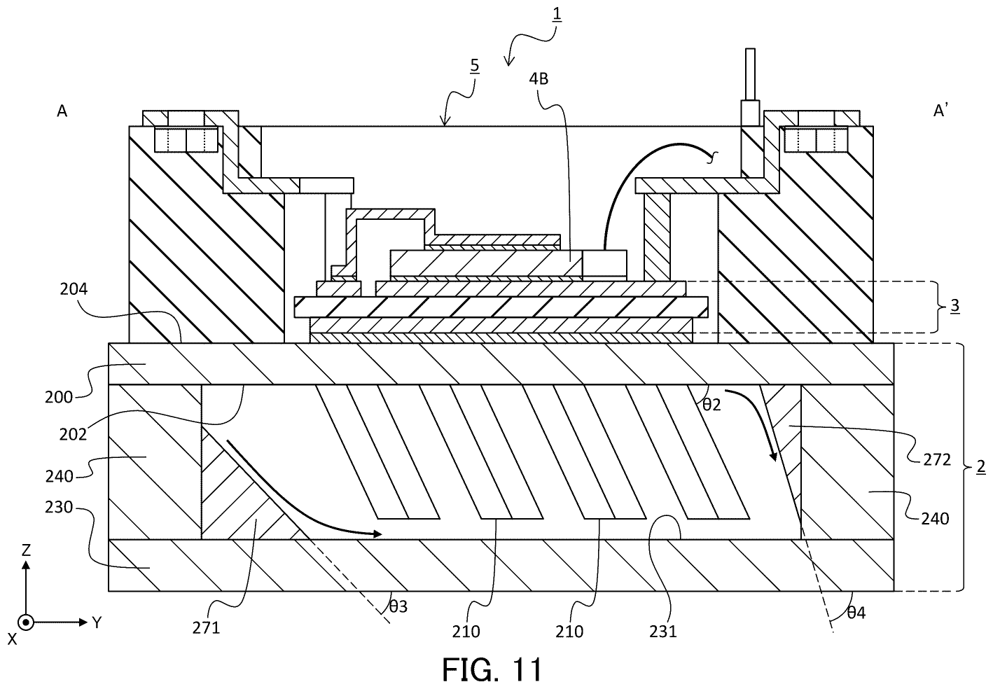

FIG. 11 is a side sectional view illustrating a first modification of the configuration of the cooler. FIG. 11 illustrates, in right side view, a portion on the left of line A-A′ of the semiconductor device 1 taken along line A-A′ in FIG. 1. In a cooler 2 of a semiconductor device 1 illustrated in FIG. 11, prevention members 271 and 272 for preventing refrigerant flow from upstream to downstream and promoting stirring of the refrigerant are disposed one-to-one at corners where stirring of the refrigerant by fins 210 is less likely to occur in side view in a flow path 260 for refrigerant defined by a top plate 200, a bottom plate 230, and a peripheral wall 240. The distance from the left end face of the flow path 260 for refrigerant illustrated in FIG. 11 to the side face of each fin 210 increases downward, and thus if the prevention member 271 is not disposed, the refrigerant having moved to the lower end side along the left end face is less likely to return to the central portion in the horizontal direction. Further, the distance from the right end face of the flow path 260 for refrigerant illustrated in FIG. 11 to the side face of each fin 210 decreases downward, and thus if the prevention member 272 is not disposed, the refrigerant flowing along the upper right corner of the flow path 260 is less likely to move downward. As described above, in a case where a portion is present in the flow path 260 for refrigerant where stirring of the refrigerant is less likely to occur depending on the extending direction and disposition of each fin 210 in side view, disposition of the prevention members 271 and 272 results in promoting the stirring of the refrigerant. For example, the prevention member 271 disposed at the lower left corner of the flow path 260 for refrigerant illustrated in FIG. 11 has an inclined face having a lower portion that is further displaced to the central portion in the horizontal direction, and can guide the refrigerant having moved to the lower end side along the left side face to the central portion in the horizontal direction. In addition, the prevention member 272 disposed at the upper right corner of the flow path 260 for refrigerant illustrated in FIG. 11 has an inclined face in contact with a lower face 202 of the top plate 200 at an obtuse angle, and can prevent the refrigerant moving in the direction of the right end face along the lower face 202 from staying at the upper right corner and guide the refrigerant to the lower end side of the flow path.

Note that the angles θ3 of the inclined face of the prevention member 271 and the angle θ4 of the inclined face of the prevention member 272 disposed in the flow path 260 for refrigerant in side view are not limited to specific angles. As illustrated in FIG. 11, the angles θ3 and θ4 of the inclined faces of the prevention members 271 and 272 may be different from the angle θ2 in the extending direction of each fin 210. In addition, the cross-sectional shapes of the prevention members 271 and 272 in side view are not limited to triangle illustrated in FIG. 11. Further, a prevention member different from the prevention members 271 and 272 illustrated in FIG. 11 may be disposed in the flow path 260 for refrigerant. Instead of disposing the prevention members 271 and 272, for example, in order to define the flow path 260 for refrigerant, the shape of any of the top plate 200, the bottom plate 230, and the peripheral wall 240 may be a shape having an inclined face corresponding to the inclined faces of the prevention members 271 and 272.

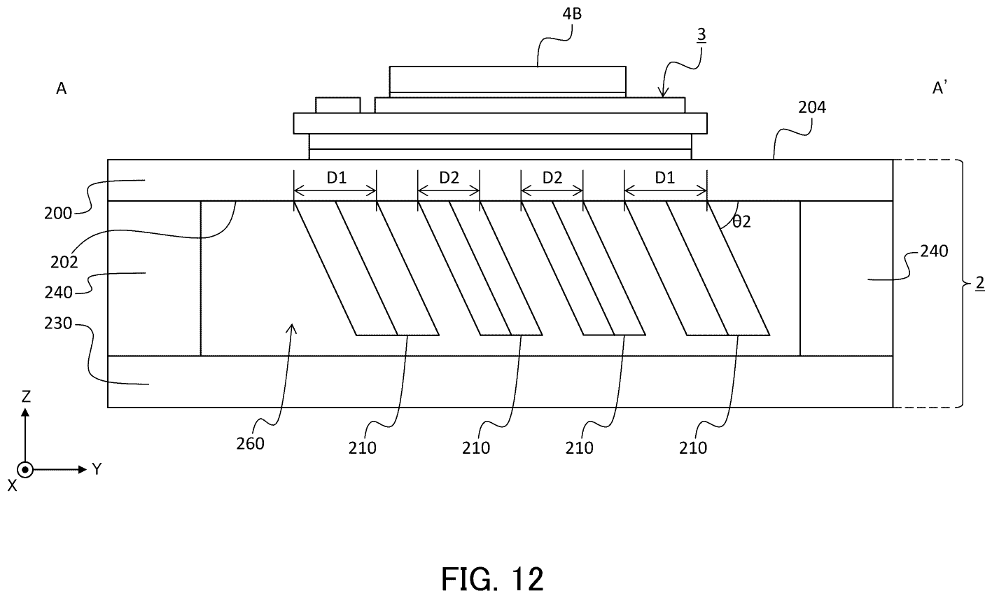

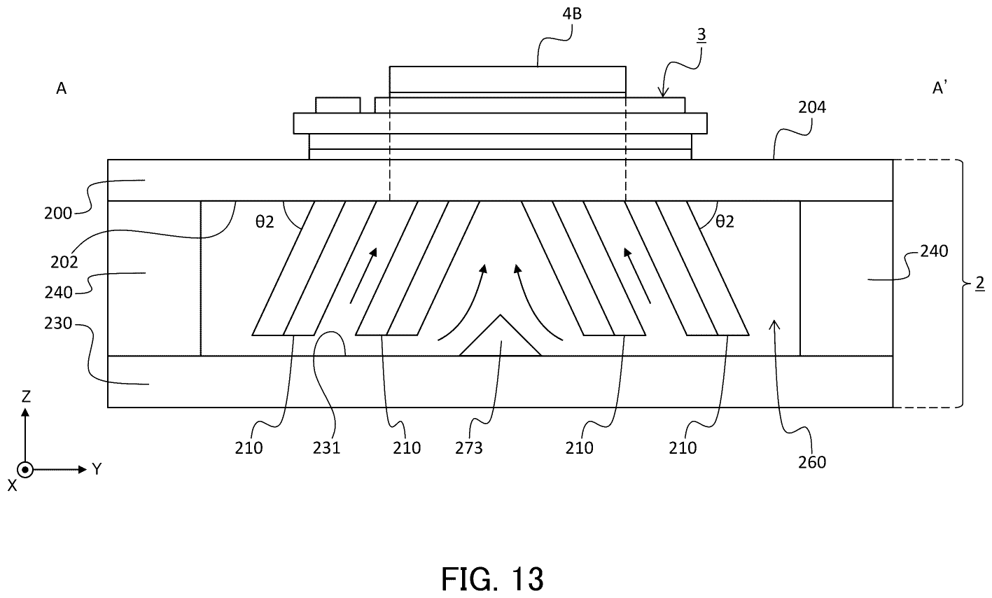

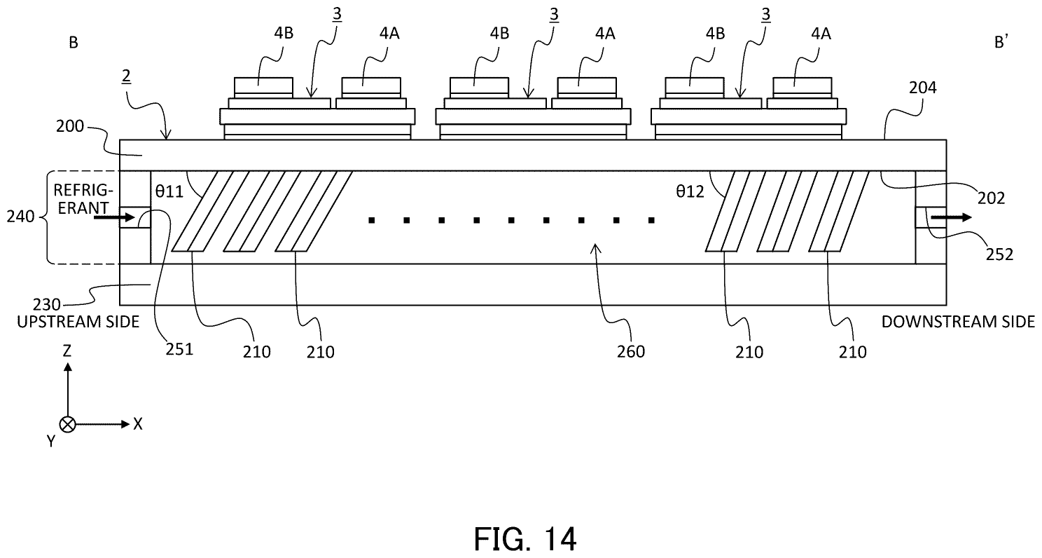

FIG. 12 is a side sectional view for explaining a first modification of the fin arrangement. FIG. 13 is a side sectional view for explaining a second modification of the fin arrangement. FIG. 14 is a side sectional view for explaining a third modification of the fin arrangement. Note that in FIGS. 12 to 14, some components disposed on a top plate 200 are not illustrated, and hatching indicating the cross section of the components is not given.

In the case of the fins 210 of the cooler 2 according to the above-described embodiments, all the fins 210 may be identical in a single shape, or may include fins 210 having two or more shapes. For example, FIG. 12 illustrates an example in which two types of fins 210 each having a first bottom face (and a second bottom face) different in size are disposed on a lower face 202 of the top plate 200. The four fins 210 illustrated in FIG. 12 each having the first bottom face that is square in shape, and the size D1 of the two fins 210 disposed one-to-one at one end and the other end in the horizontal direction is larger than the size D2 of the two fins 210 disposed at the central portion in the horizontal direction. In such a manner, due to increasing the size of the fins 210 (thickening the fins 210) disposed on both sides in the horizontal direction in side view, the area of each inclined side faces is increased, and for example, the refrigerant flowing through the positions closer to the ends in the horizontal direction in the flow path 260 for refrigerant in side view is easily guided to the central portion in the horizontal direction.

In addition, for example, as illustrated in FIG. 13, fins 210 may have two extending directions in side view. Among the four fins 210 illustrated in FIG. 13, the two fins 210 on the left side of the center in the horizontal direction each extend downward at an angle θ2 in a direction closer to the left end face of a flow path 260, and the two fins 210 on the right side of the center in the horizontal direction each extend downward at an angle θ2 in a direction closer to the right end face of the flow path 260. The fins 210 are disposed so as to be tapered from a lower layer portion to an upper layer portion in the flow path 260 for refrigerant in side view, so that the refrigerant flowing through the ends in the horizontal direction of the lower layer portion in the flow path 260 for refrigerant can be uniformly guided to the upper layer portion in side view. Therefore, the deviation of the temperature distribution of the refrigerant in side view can be reduced. Note that in a case where the fins 210 are arranged as described above with reference to FIG. 13, for example, a prevention member 273 that is different from the fins 210 and prevents the downstream flow of the refrigerant to guide the refrigerant to the upper layer portion may be disposed on an upper face 231 of a bottom plate 230.

Further, for example, as illustrated in FIG. 14, fins 210 may have two or more directions in front view. Among the six fins 210 illustrated in FIG. 14, an angle θ11 in the extending direction of each of the three fins 210 on the upstream side is smaller than an angle θ12 in the extending direction of each of the three fins 210 on the downstream side. As described above with reference to FIG. 9, the value of thermal resistance and pressure drop change depending on the angle of the extending direction of each fin 210. Based on the graph of FIG. 9, for example, assuming that the angle θ11 in the extending direction of each of the three fins 210 on the upstream side in front view is set to 75 degrees and the angle θ12 in the extending direction of each of the three fins 210 on the downstream side is set to 85 degrees, the value of thermal resistance and pressure drop on the upstream side are smaller than the value of thermal resistance and pressure drop on the downstream side. Thus, in a cooler 2 illustrated in FIG. 14, for example, refrigerant easily flows from upstream to downstream on the upstream side of a flow path 260 as compared with the downstream side thereof. Therefore, for example, a temperature rise of the refrigerant due to heat exchange between the fins 210 and the refrigerant on the upstream side of the flow path 260 can be reduced and a decrease in cooling efficiency on the downstream side of the flow path 260 can be prevented.

The cooler 2 according to the present embodiment is not limited to the above-described configuration, and for example, the peripheral wall 240 may be integrated with either the top plate 200 or the bottom plate 230.

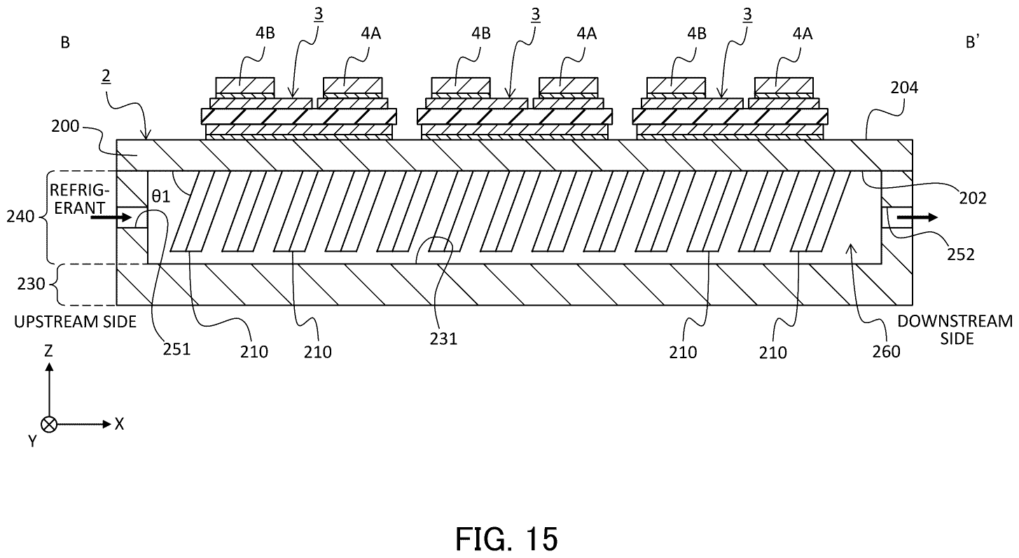

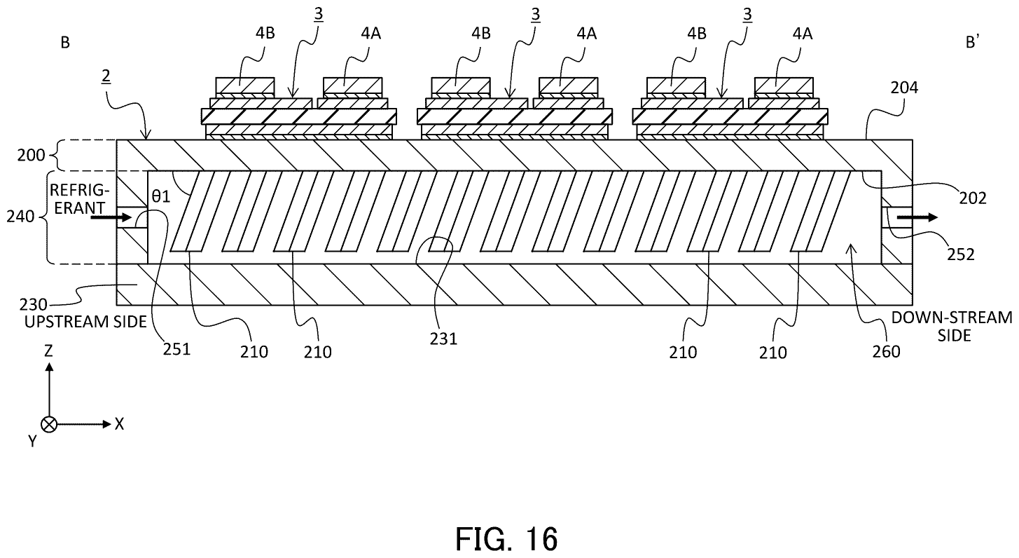

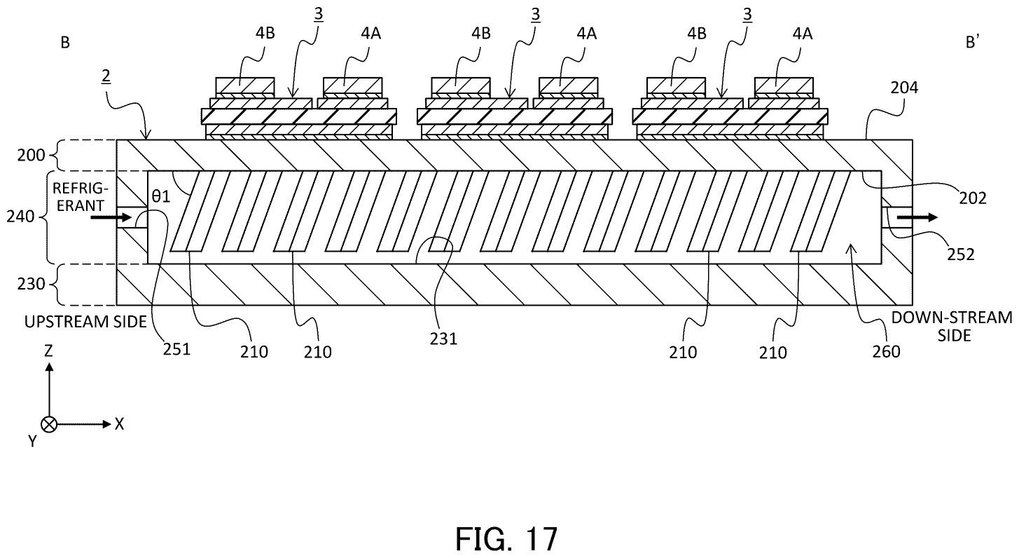

FIG. 15 is a side sectional view illustrating a second modification of the configuration of the cooler. FIG. 16 is a side sectional view illustrating a third modification of the configuration of the cooler. FIG. 17 is a side sectional view illustrating a fourth modification of the configuration of the cooler. All the drawings correspond to FIG. 4.

A cooler 2 may include a peripheral wall 240 and a bottom plate 230 that are integrated as illustrated in FIG. 15, or a cooler 2 may include a peripheral wall 240 and a top plate 200 that are integrated as illustrated in FIG. 16. In addition, although not illustrated, in the cooler 2, for example, a part of the peripheral wall 240 may be integrated with the bottom plate 230, and the remaining part of the peripheral wall 240 may be integrated with the top plate 200. Further, as illustrated in FIG. 17, a cooler 2 may include a top plate 200, a bottom plate 230, and a peripheral wall 240 that are integrated, and a cavity formed by the top plate 200, the bottom plate 230, and the peripheral wall 240 may serve as a flow path 260 for refrigerant. Such a cooler 2 can be manufactured, for example, with a 3D printer.

The fins 210 of the cooler 2 according to the present embodiment may each have an upper end connected to the lower face 202 of the top plate 200 and a lower end connected to the upper face of the bottom plate 230.

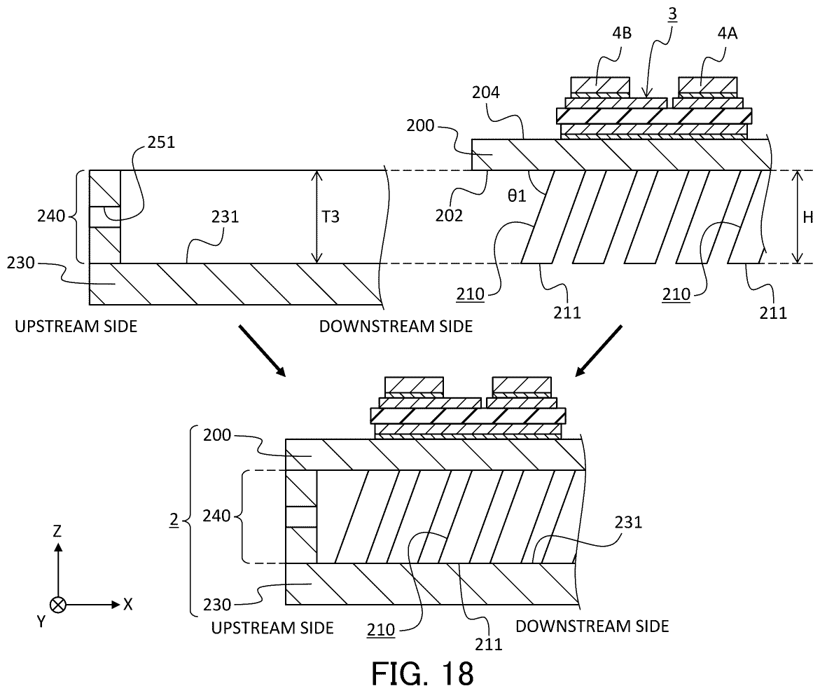

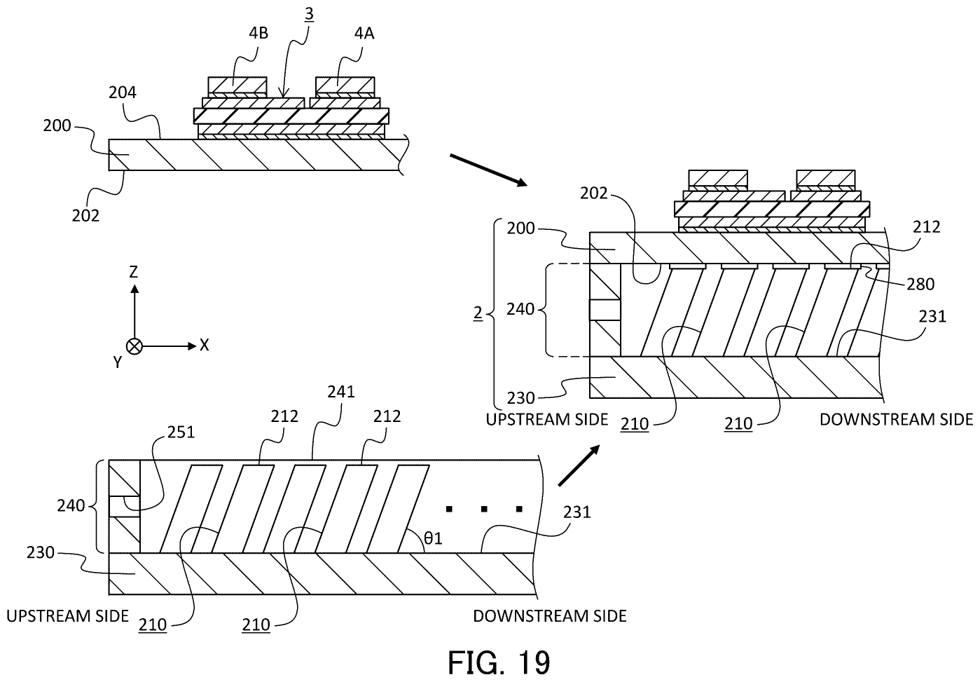

FIG. 18 is a view for explaining a fifth modification of the configuration of the cooler. FIG. 19 is a view for explaining a sixth modification of the configuration of the cooler. FIGS. 18 and 19 each correspond to a portion including the left end of the cooler 2 illustrated in FIG. 4. In FIGS. 18 and 19, the underlined reference numeral 210 is intended to refer to the entirety of each fin.

In a cooler 2 illustrated in FIG. 18, the height H of each fin 210 extending downward from a lower face 202 of a top plate 200 and the thickness T3 of a peripheral wall 240 substantially coincide with each other. Thus, due to integration of a top plate 200, a peripheral wall 240, and a bottom plate 230, a lower face 211 of each fin 210 is in contact with an upper face 231 of the bottom plate 230. Each of a plurality of fins 210 in a cooler 2 illustrated in FIG. 19 extends upward not from a lower face 202 of a top plate 200 but from an upper face 231 of a bottom plate 230. In order to form a plurality of fins 210 on an upper face 231 of a bottom plate 230, each of the fins 210 is formed such that the fin 210 has a portion that is displaced toward the downstream side as distanced from the upper face 231 of the bottom plate 230 in front view. The height from the upper face 231 of the bottom plate 230 to an upper face 212 of the fin 210 is substantially matched with the thickness T3 of a peripheral wall 240. In FIG. 19, the position of the upper face 212 of each fin 210 in the Z direction is lower than the position of an upper face 241 of a peripheral wall 240 in the Z direction. In such a cooler 2, for example, due to integration of the top plate 200, the peripheral wall 240, and the bottom plate 230 with the fins 210 formed thereon are integrated, the upper face 212 of each fin 210 and the lower face 202 of the top plate 200 are connected through a member 280 having high thermal conductivity.

Note that the configuration of the cooler 2 in which an upper end of each fin 201 is connected to the lower face 202 of the top plate 200 and a lower end of the fin 201 is connected to the upper face 231 of the bottom plate 230 is not limited to the configurations illustrated in FIGS. 18 and 19. For example, the lower face 211 of the fin 210 extending downward from the lower face 202 of the top plate 200 and the upper face 231 of the bottom plate 230 may be connected through a member 280 having high thermal conductivity. Alternatively, for example, the upper face 212 of the fin 210 extending upward from the upper face 231 of the bottom plate 230 and the lower face 202 of the top plate 200 may be in close contact with each other without the member 280.

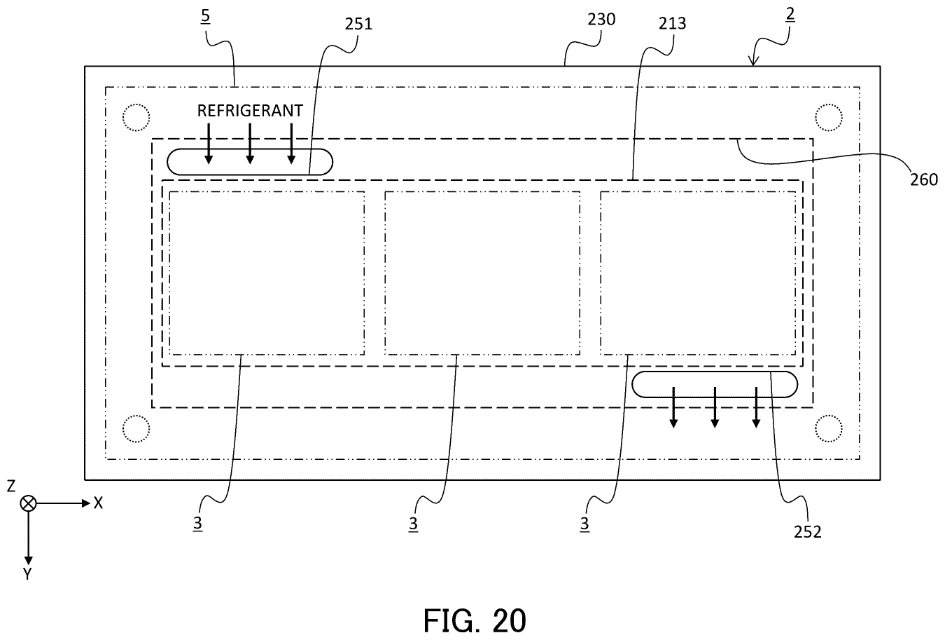

FIG. 20 is a bottom view illustrating a modification of the positional relationship between the inlet and the outlet for refrigerant in the cooler.

In each cooler 2 illustrated in, for example, FIG. 4 and FIGS. 14 to 19, the inlet 251 for refrigerant is provided on the left side face and the outlet 252 for refrigerant is provided on the right side in front view. However, the positions of the inlet 251 and the outlet 252 for refrigerant in the cooler 2 according to the present invention are not limited to such positions. For example, as illustrated in FIG. 20, at diagonal positions of a region where a flow path 260 for refrigerant is defined in a cooler 2 in plan view (bottom view), an inlet 251 and an outlet 252 for refrigerant are provided such that a region 213 where a plurality of fins 210 is disposed is interposed between the inlet 251 and the outlet 252.

Similarly, regardless of the configurations of a top plate 200, a bottom plate 230, and a peripheral wall 240, the inlet 251 and the outlet 252 may be each disposed on a side face, a bottom face, or an upper face; one may be disposed on the side face and the other may be disposed on either of the upper face or the lower face; or one may be disposed on the upper face and the other may be disposed on the lower face.

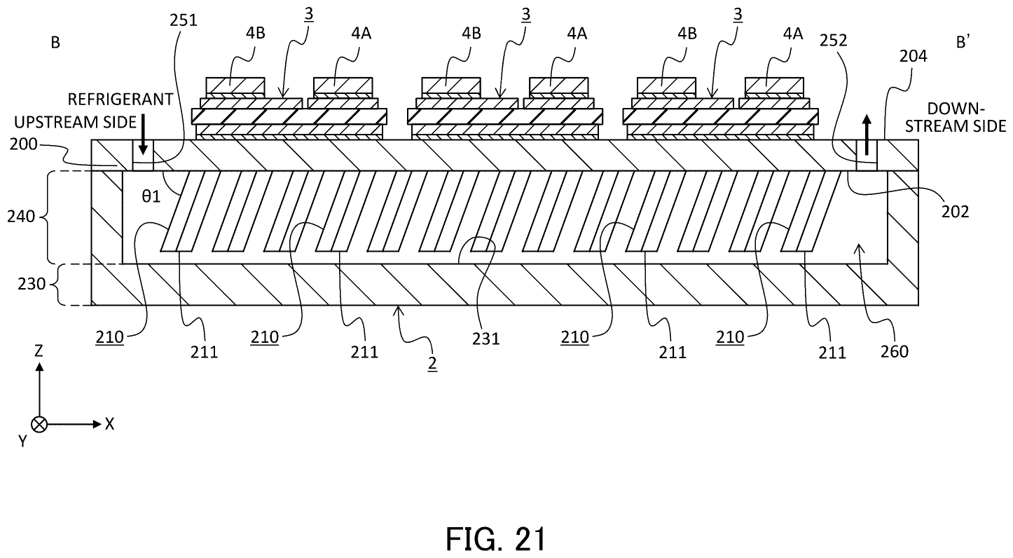

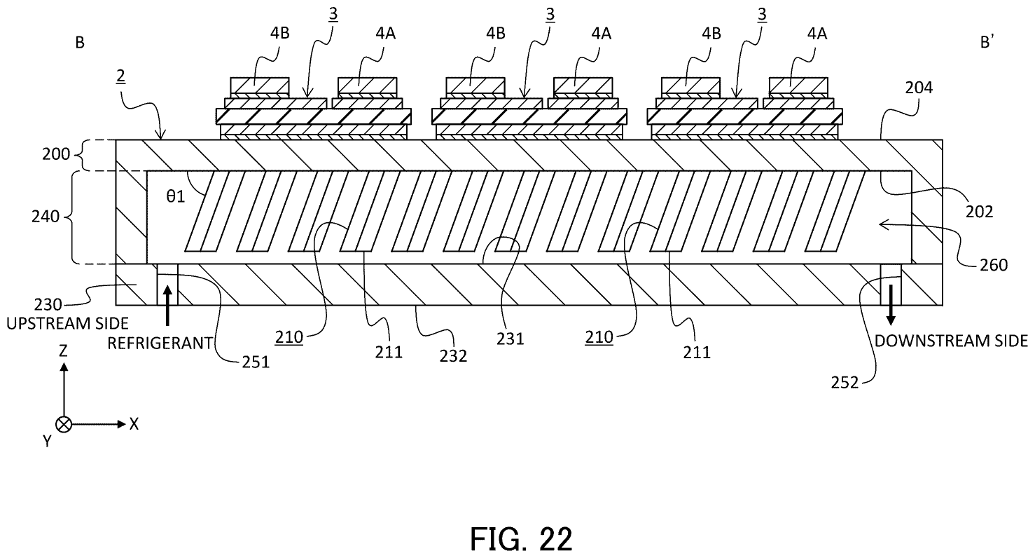

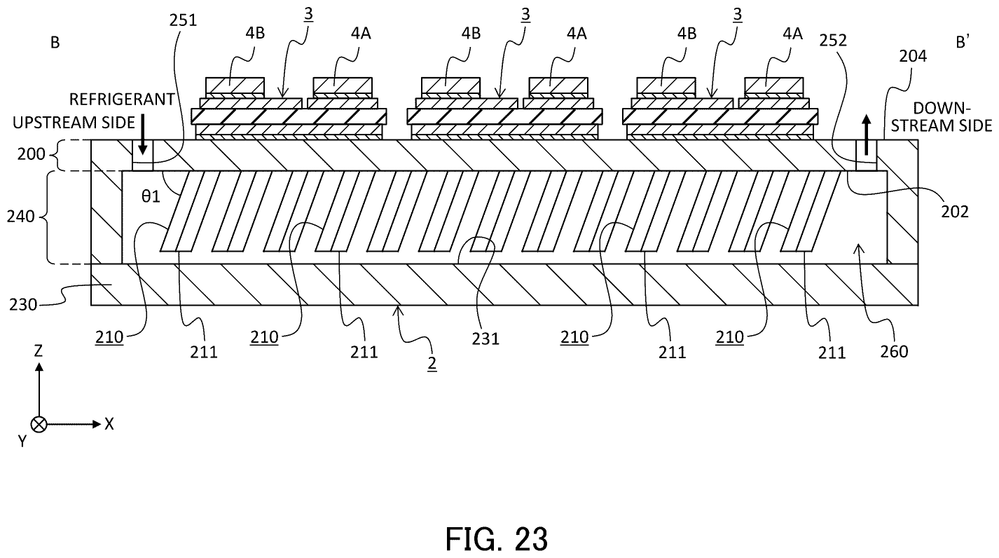

FIG. 21 is a side sectional view illustrating a first modification of the configuration of the cooler and the positional relationship between the inlet and the outlet for refrigerant. FIG. 22 is a side sectional view illustrating a second modification of the configuration of the cooler and the positional relationship between the inlet and the outlet for refrigerant. FIG. 23 is a side sectional view illustrating a third modification of the configuration of the cooler and the positional relationship between the inlet and the outlet for refrigerant. All the drawings correspond to FIG. 4.

In a cooler 2 illustrated in FIG. 21, a peripheral wall 240 is integrated with a bottom plate 230, and an inlet 251 and an outlet 252 is provided to a top plate 200 as through holes penetrating from an upper face 204 to a lower face 202 of the top plate 200. In a cooler 2 illustrated in FIG. 22, a peripheral wall 240 is integrated with a top plate 200, and an inlet 251 and an outlet 252 are provided to a bottom plate 230 as through holes penetrating from an upper face 231 to a lower face 232 of the bottom plate 230. In a cooler 2 illustrated in FIG. 23, a peripheral wall 240 is integrated with a top plate 200, and an inlet 251 and an outlet 252 are provided to the top plate 200 as through holes penetrating from an upper face 204 to a lower face 202 of the top plate 200. Note that as described above, the positional relationship between the inlet 251 and the outlet 252 may be another positional relationship. For example, in a cooler 2, an inlet 251 may be provided to a top plate 200, and an outlet 252 may be provided to a bottom plate 230 or a peripheral wall 240.

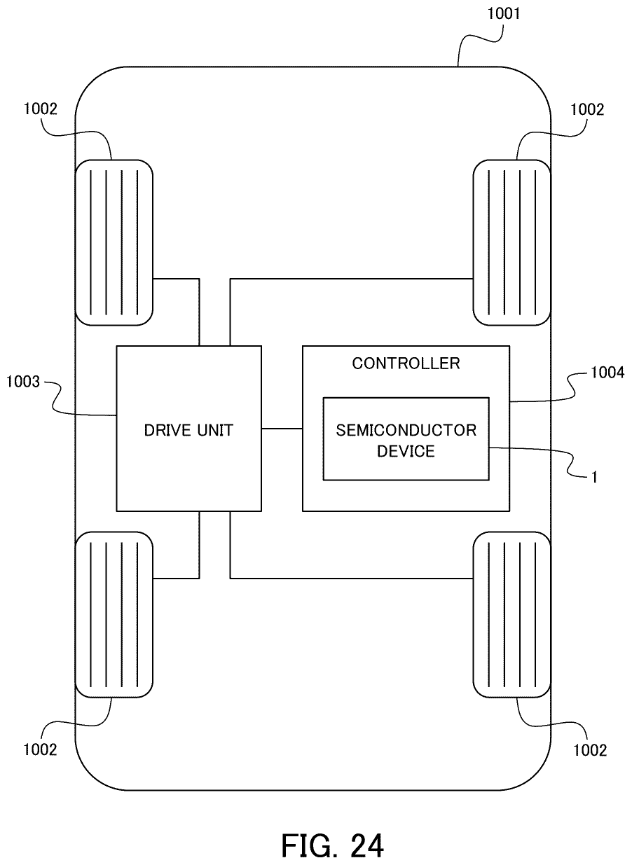

The semiconductor device 1 according to the above-described embodiments is not limited to a specific application, but in particular, the semiconductor device 1 is suitable for use in a high-temperature environment. For example, the semiconductor device 1 according to the above-described embodiments may be applied to an electric power converter such as an inverter for an in-vehicle motor. A vehicle to which the semiconductor device 1 according to the present invention is applied is described with reference to FIG. 24.

FIG. 24 is a schematic plan view illustrating an exemplary vehicle to which the semiconductor device according to the present invention is applied. A vehicle 1001 illustrated in FIG. 24 is, for example, a four-wheeled vehicle including four wheels 1002. The vehicle 1001 may be, for example, an electric vehicle that drives its wheels by a motor, or a hybrid vehicle using power of an internal combustion engine in addition to the motor. In addition, the vehicle to which the semiconductor device 1 is applied is not limited to a four-wheeled vehicle, and may be, for example, a two-wheeled vehicle or a railway vehicle.

The vehicle 1001 includes a drive unit 1003 that applies power to the wheels 1002, and a controller 1004 that controls the drive unit 1003. The drive unit 1003 may include, for example, at least one of an engine, a motor, and a hybrid of an engine and a motor.

The controller 1004 performs control (e.g., electric power control) on the drive unit 1003. The controller 1004 includes the semiconductor device 1 including a cooler 2 according to the above-described embodiments. The semiconductor device 1 may be configured to perform electric power control on the drive unit 1003.

The embodiments of the cooler 2 and the semiconductor device 1 according to the present invention is not limited to the above-described embodiments, and thus various changes, substitutions, and modifications may be made without departing from the spirit of the technical idea. Further, if the technical idea can be achieved in another manner due to the progress of the technology or by another derived technology, the technical idea may be carried out by using the manner. Therefore, the claims cover all embodiments that may be included within the scope of the technical idea.

Hereinafter, feature points in the above-described embodiments will be summarized.

A cooler according to such an embodiment as described above includes: a top plate having a first face on which a dissipation face is formed; a bottom plate disposed counter to the top plate, the bottom plate being larger in thickness than the top plate; a plurality of fins connected to at least the top plate; a peripheral wall formed between the top plate and the bottom plate, the peripheral wall surrounding the outer periphery of the fins; a flow path for refrigerant formed in a space surrounded by the top plate, the bottom plate, the fins, and the peripheral wall; an inlet for the refrigerant provided to the top plate, the bottom plate, or the peripheral wall on one end side in a first direction of the flow path for the refrigerant; and an outlet for the refrigerant provided to the top plate, the bottom plate, or the peripheral wall on another end side in the first direction of the flow path for the refrigerant, in which the fins each include an inclined portion extending in a direction in which the inclined portion is displaced toward the inlet for the refrigerant as distanced from the first face of the top plate in first plan view when viewed in a second direction perpendicular to the first direction, the inclined portion extending in a direction in which the inclined portion is displaced in the second direction as distanced from the first face of the top plate in second plan view when viewed in the first direction.

In the cooler according to the embodiment, the inclined portion of each of the fins has an extending direction at an angle of 45 degrees or more and less than 90 degrees to the first face of the top plate in the first plan view, the inclined portion of each of the fins having an extending direction at an angle of 45 degrees or more and less than 90 degrees to the first face of the top plate in the second plan view.

In the cooler according to the embodiment, the flow path for the refrigerant is configured to prevent the refrigerant from flowing in the first direction to promote stirring of the refrigerant.

The cooler according to the embodiment further includes a prevention member disposed in the flow path for the refrigerant, the prevention member being configured to prevent the refrigerant from flowing in the first direction, the prevention member being different from the fins.

In the cooler according to the embodiment, the fins each have a bottom face that is square in shape in plan view of the first face of the top plate, the fins each being disposed such that the bottom face square in shape has sides each having an extending direction at an angle of 45 degrees to the first direction.

In the cooler according to the embodiment, the fins include a plurality of types of fins having respective bottom faces different in size in plan view of the first face of the top plate.

In the cooler according to the embodiment, from among the types of fins, a fin disposed at an end in the second direction is larger in size than a fin disposed at a central portion in the second direction.

In the cooler according to the embodiment, the fins include a plurality of types of fins including a type of fin and another type of fin, and a combination of respective extending directions of the inclined portion of the type of fin in the first plan view and the second plan view is different from a combination of respective extending directions of the inclined portion of the another type of fin in the first plan view and the second plan view.

In the cooler according to the embodiment, in the second plan view, the fins include a fin including the inclined portion that is displaced toward one end side in the second direction as distanced from the top plate and another fin including the inclined portion that is displaced toward another end side in the second direction as distanced from the top plate.

In the cooler according to the embodiment, the respective inclined portions of the fins have respective extending directions that are each based on a distance from an upstream side of the refrigerant in the first plan view, the extending directions being different from each other.

A semiconductor device according to the above-described embodiments includes: the cooler; a wiring board disposed on a face of the top plate, the face being opposite to the first face of the top plate; and a semiconductor element disposed on the face of the top plate.

A vehicle according to the above-described embodiments includes the semiconductor device.

### INDUSTRIAL APPLICABILITY

As described above, the present invention has an effect that the cooling performance of a cooler applied to a semiconductor device can be improved, and in particular, it is useful to apply the present invention to a semiconductor device for an industrial component or electrical/electronic component and a vehicle.

The present application is based on Japanese Patent Application No. 2023-100938 filed on Jun. 20, 2023. All the contents are included herein.

1. A cooler, comprising:
a top plate having a first surface that forms a heat dissipation surface;
a bottom plate disposed opposite the top plate, the bottom plate having a thickness greater than a thickness of the top plate;
a plurality of fins, each connected to the heat dissipation surface, each fin having an inclined portion extending in an extending direction, the inclined portion having a first end and a second end opposite to each other in the extending direction;
a peripheral wall surrounding an outer periphery of the plurality of fins between the top plate and the bottom plate, a refrigerant flow path for a refrigerant being formed within a refrigerant space enclosed by the top plate, the bottom plate, the plurality of fins, and the peripheral wall;
a refrigerant inlet provided at one side of the top plate, the bottom plate, or the peripheral wall in a first direction parallel to the heat dissipation surface; and
a refrigerant outlet provided at an opposite side of the top plate, the bottom plate, or the peripheral wall in the first direction, wherein
in a first side view of the cooler, viewed from a second direction perpendicular to the first direction and parallel to the heat dissipation surface, the inclined portion is inclined such that the second end is displaced toward the refrigerant inlet relative to the first end, and
in a second side view of the cooler, viewed from the first direction, the inclined portion is inclined such that the second end is displaced toward one of opposite sides of the peripheral wall in the second direction relative to the first end.

2. The cooler according to claim 1, wherein
the inclined portion of each fin extends in the extending direction, to form
a first angle between the first direction and a projection of the extending direction onto a first plane that contains the first direction and is orthogonal to the heat dissipation surface, and
a second angle between the second direction and a projection of the extending direction onto a second plane that contains the second direction and is orthogonal to the heat dissipation surface, and
the first angle and the second angle are equal to or greater than 45 degrees and less than 90 degrees.

3. The cooler according to claim 1, wherein the refrigerant flow path is configured to prevent the refrigerant from flowing in the first direction to promote stirring of the refrigerant.

4. The cooler according to claim 3, further comprising a prevention member, which is distinct from the plurality of fins, disposed in the refrigerant flow path, the prevention member being configured to prevent the refrigerant from flowing from the refrigerant inlet toward the refrigerant outlet in the first direction.

5. The cooler according to claim 1, wherein
the inclined portion of each fin has an end surface at the second end thereof that is square in shape and faces the bottom plate, and
the first direction and a direction of one side of the end surface parallel to the heat dissipation surface form an angle of 45 degrees.

6. The cooler according to claim 1, wherein
the inclined portion of each fin has an end surface at the second end thereof, facing the bottom plate, and
the plurality of fins includes a first fin and a second fin, the end surface of the inclined portion of the first fin differing in size from that of the second fin.

7. The cooler according to claim 6, wherein
the second fin is positioned closer to a center of the refrigerant space in the second direction than the first fin, and
the end surface of the first fin is larger in size than that of the second fin.

8. The cooler according to claim 1, wherein
the inclined portion of each fin extends in the extending direction, to form
a first angle between the first direction and a projection of the extending direction onto a first plane that contains the first direction and is orthogonal to the heat dissipation surface, and
a second angle between the second direction and a projection of the extending direction onto a second plane that contains the second direction and is orthogonal to the heat dissipation surface, and
the plurality of fins includes a first fin and a second fin, at least one of the first or second angle of the first fin differs from a corresponding first or second angle of the second fin.

9. The cooler according to claim 1, wherein
the plurality of fins includes a first fin and a second fin, and
the inclined portions of the first fin and the second fin respectively extend such that the second ends thereof are displaced toward respective ones of the opposite sides of the peripheral wall in the second direction relative to the first ends thereof.

10. The cooler according to claim 1, wherein
the inclined portion of each fin extends in the extending direction, to form a first angle between the first direction and a projection of the extending direction onto a first plane that contains the first direction and is orthogonal to the heat dissipation surface, and
the plurality of fins includes a first fin and a second fin, the second fin being positioned at a distance from the refrigerant inlet in the first direction than a distance of the first fin from the refrigerant inlet, the first angle of the first fin differing from the first angle of the second fin.

11. A semiconductor device, comprising:
the cooler according to claim 1;
a wiring board disposed on a second surface of the top plate opposite the first surface of the top plate; and
a semiconductor element disposed on the second surface of the top plate.

12. A vehicle comprising the semiconductor device according to claim 11.
